(19) United States
(12) Patent Application Publication
(10) Pub. No.: US 2010/0193011 A1
(43) Pub. Date: Aug. 5, 2010

(54) MATERIALS FOR SOLAR CONCENTRATORS AND DEVICES, METHODS AND SYSTEM USING THEM

(76) Inventors: Jonathan Mapel, East Boston, MA (US); Marc Baldo, Cambridge, MA (US); Carlijn L. Mulder, Boston, MA (US); Michael Currie, Groton, MA (US); Michael Segal, Cambridge, MA (US); Carmel Rotschild, Brookline, MA (US)

Correspondence Address: LANDO & ANASTASI, LLP, ONE MAIN STREET, SUITE 1100, CAMBRIDGE, MA, 02142, US

(21) Appl. No.: 12/691,459

(22) Filed: Jan. 21, 2010

Related U.S. Application Data
(60) Provisional application No. 61/146,550, filed on Jan. 22, 2009.

(51) Int. Cl. H01L 31/052; H01L 31/00; G02B 7/182

(52) U.S. Cl. 136/246; 136/259; 359/851

(57) ABSTRACT

Solar concentrators are disclosed that improve the efficiency of PV cells and systems using them. The solar concentrators may be designed such that they include one or more chromophore assemblies, anti-Stokes materials or other suitable materials that emit light to a PV cell. Various materials and components of the solar concentrators are also described.

### CROSS REFERENCE TO RELATED APPLICATIONS

This application claims priority under 35 U.S.C. §119(e) to co-pending U.S. Provisional Application No. 61/146,550 entitled “MATERIALS FOR SOLAR CONCENTRATORS AND DEVICES, METHODS AND SYSTEMS USING THEM,” filed on Jan. 22, 2009, which is herein incorporated by reference in its entirety.

### GOVERNMENT SUPPORT

This invention was made with government support under Grant No. DBI0403781 awarded by the NSF and Grant No. DE-FG02-07ER46474 awarded by the DOE. The government has certain rights in this invention.

### FIELD OF THE TECHNOLOGY

Certain embodiments of the technology disclosed herein relate generally to materials for use in solar concentrators and devices, methods and systems using them. More particularly, certain examples disclosed herein are directed to materials for solar concentrators that may be produced at a lower cost.

### BACKGROUND

Solar cells may be used to convert solar energy into electrical energy. Many solar cells are inefficient, however, with a small fraction of the incident solar energy actually being converted into a usable current. Also, the high cost of solar cells limits their use as a renewable energy source.

### SUMMARY OF INVENTION

In accordance with a first aspect, a solar concentrator comprising a substrate and chromophore assembly comprising a plurality of chromophores disposed on or in the substrate in a manner that at least one of the plurality of chromophores can receive at least some optical radiation is provided. In certain examples, the chromophore assembly comprises an emitting chromophore effective to receive at least some energy by Förster energy transfer from the at least one chromophore of the chromophore assembly and emit at least some of the received energy at a wavelength that is red-shifted from the wavelength absorbed by the at least one of the plurality of chromophores in the chromophore assembly.

In certain embodiments, the at least one chromophore that transfers energy to the emitting chromophore can be part of the chromophore assembly. In other embodiments, the at least one chromophore that transfers energy to the emitting chromophore is separate from the chromophore assembly. In some examples, the chromophore assembly comprises a chromophore complex or a chromophore aggregate. In certain examples, the chromophore assembly is selected from the group consisting of a chlorin, a phycobilosome, a porphyrin, a cyanine dye and a perylene bisimide dye. In some examples, the substrate may be a glass comprising a refractive index of at least 1.7. In other examples, the concentrator may further comprise at least one wavelength selective minor disposed on the substrate, the wavelength selective mirror configured to transmit incident light in a first wavelength range and to reflect incident light in a second wavelength range. In some examples, the concentrator may further comprise a polar matrix in which the chromophore assembly is disposed. In some embodiments, the concentrator may be optically coupled to a first photovoltaic cell. In other examples, the concentrator may be optically coupled to a second photovoltaic cell, wherein the efficiency of the first and second photovoltaic cells are different.

In another aspect, a solar concentrator comprising a substrate and at least two chromophores disposed on or in the substrate in a manner that at least one of the chromophores can receive at least some optical radiation is disclosed. In some examples, one of the at least two chromophores comprise an anti-Stokes material and the other of the at least two chromophores is effective to receive energy from the anti-Stokes material by Förster energy transfer and emit at least some of the transferred energy at a wavelength that is blue-shifted from the wavelength absorbed by the anti-Stokes material.

In certain embodiments, the anti-Stokes material is selected from the group consisting of lanthanide complexes, thulium doped silicate glasses, europium complexes, terbium complexes, samarium complexes, dysprosium complexes, inorganic rare earth ions, inorganic rare earth crystals, bulk phosphor material, europium-activated yttriumoxysulphide, rare earth oxide nanocrystals, fluorides containing europium, chlorides containing europium, lanthanide phosphors, inorganic crystal lattice with trivalent rare earth dopants, yttriumoxysulphide activated with erbium and ytterbium, upconverting phosphor nanopowder from TAL Materials, Inc. (Ann Arbor, Mich.), anti-Stokes phosphors FCD-546-1, FCD-546-2, FCD-546-3, FCD-660-2, FCD-660-3 and FCD-660-4 from Luminophor JSC (Stavropol, Russia), anti-Stokes phosphor LPG-IR-3 from Platan R&DI (Moscow Region, Russia) and laser detection “anti-Stokes” phosphors PTIR545/UF, PTIR550/F and PTIR660/F from Phosphor Technology Ltd. (Stevenage, England). In other embodiments, the chromophore that receives energy from the anti-Stokes material is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, pyradines, indocyanine green, styryls (Lambdachrome series), dioxazines, naphthalimides, thiazines, stilbenes, IR132, IR144, IR140, and Dayglo Sky Blue (D-286) and Columbia Blue (D-298). In some examples, the chromophore that receives energy from the anti-Stokes material comprises a chromophore assembly. In other examples, the chromophore assembly is selected from the group consisting of a chlorin, a phycobilosome, a porphyrin, a cyanine dye and a perylene bisimide dye. In some examples, the substrate may be a glass comprising a refractive index of at least 1.7. In certain embodiments, the concentrator may further comprise at least one wavelength selective minor disposed on the substrate, the wavelength selective minor configured to transmit incident light in a first wavelength range and to reflect incident light in a second wavelength range. In some embodiments, the concentrator may further comprise a polar matrix in which the anti-Stokes material is disposed. In some examples, a first photovoltaic cell may be optically coupled to the solar concentrator. In other examples, a second photovoltaic cell may be optically coupled to the solar concentrator, wherein the efficiency of the first and second photovoltaic cells is different.

In an additional aspect, a solar concentrator comprising a substrate, and a film comprising a chromophore assembly and disposed on or in the substrate in a manner to receive at least some optical radiation is provided. In certain examples, the chromophore assembly comprises at first chromophore effective to absorb at least one wavelength of at least some of the optical radiation without substantial light emission of the absorbed optical radiation, a second chromophore in the chromophore assembly that is effective to receive energy from the first chromophore and to transfer energy to a third chromophore in the chromophore assembly, the third chromophore effective to emit at least some of the transferred energy at a wavelength that is red-shifted from the at least one wavelength absorbed by the first chromophore.

In certain embodiments, at least one chromophore in the film is separate from the chromophore assembly. In other embodiments, the first chromophore is present in the film at a concentration least two times greater than the concentration of the third chromophore in the film. In some examples, the chromophore assembly comprises a chromophore complex or a chromophore aggregate. In additional examples, the chromophore assembly is selected from the group consisting of a chlorin, a phycobilosome, a porphyrin, a cyanine dye and a perylene bisimide dye. In other examples, the substrate can be a glass comprising a refractive index of at least 1.7. In some examples, the concentrator may further comprise at least one wavelength selective minor disposed on the substrate, the wavelength selective mirror configured to transmit incident light in a first wavelength range and to reflect incident light in a second wavelength range. In other examples, the concentrator may further comprise a polar matrix in which the chromophore assembly is disposed. In certain embodiments, the concentrator may further comprise a first photovoltaic cell optically coupled to the solar concentrator. In some embodiments, the concentrator may comprise a second photovoltaic cell optically coupled to the solar concentrator, wherein the efficiency of the first and second photovoltaic cells is different.

In another aspect, a solar concentrator comprising a substrate, and a film disposed on the substrate in a manner to receive at least some optical radiation, the film comprising at least a first chromophore comprising an anti-Stokes material and a second chromophore is provided. In certain embodiments, the anti-Stokes material of the first chromophore is effective to absorb at least one wavelength of at least some of the optical radiation and is further effective to transfer at least some energy by Förster energy transfer to the second chromophore, in which the second chromophore is effective to emit at least some of the transferred energy at a wavelength that is blue-shifted from the wavelength absorbed by the anti-Stokes material.

In certain examples, the anti-Stokes material is selected from the group consisting of lanthanide complexes, thulium doped silicate glasses, europium complexes, terbium complexes, samarium complexes, dysprosium complexes, inorganic rare earth ions, inorganic rare earth crystals, bulk phosphor material, europium-activated yttriumoxysulphide, rare earth oxide nanocrystals, fluorides containing europium, chlorides containing europium, lanthanide phosphors, inorganic crystal lattice with trivalent rare earth dopants, yttriumoxysulphide activated with erbium and ytterbium, upconverting phosphor nanopowder from TAL Materials, Inc. (Ann Arbor, Mich.), anti-Stokes phosphors FCD-546-1, FCD-546-2, FCD-546-3, FCD-660-2, FCD-660-3 and FCD-660-4 from Luminophor JSC (Stavropol, Russia), anti-Stokes phosphor LPG-IR-3 from Platan R&DI (Moscow Region, Russia) and laser detection “anti-Stokes” phosphors PTIR545/UF, PTIR550/F and PTIR660/F from Phosphor Technology Ltd. (Stevenage, England). In other examples, the chromophore that receives energy from the anti-Stokes material is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, prradines, indocyanine green, styryls (Lambdachrome series), dioxazines, naphthalimides, thiazines, stilbenes, IR132, IR144, IR140, and Dayglo Sky Blue (D-286) and Columbia Blue (D-298). In certain embodiments, the chromophore that receives energy from the anti-Stokes material comprises a chromophore assembly. In some examples, the chromophore assembly is selected from the group consisting of a chlorin, a phycobilosome, a porphyrin, a cyanine dye and a perylene bisimide dye. In other examples, the substrate can be a glass comprising a refractive index of at least 1.7. In some embodiments, the concentrator may further comprise at least one wavelength selective minor disposed on the substrate, the wavelength selective mirror configured to transmit incident light in a first wavelength range and to reflect incident light in a second wavelength range. In other examples, the concentrator may further comprise a polar matrix in which at least one of the anti-Stokes material or the second chromophore is disposed. In some examples, the concentrator may further comprise a first photovoltaic cell optically coupled to the solar concentrator. In other examples, a second photovoltaic cell may be optically coupled to the solar concentrator, wherein the efficiency of the first and second photovoltaic cells is different.

In another aspect, a solar concentrator comprising a substrate and a film disposed on the substrate in a manner to receive at least some optical radiation, the film comprising a chromophore assembly comprising at least one chromophore effective to absorb at least one wavelength of at least some of the optical radiation without substantial light emission of the absorbed optical radiation is disclosed. In certain examples, the film may further comprise a terminal chromophore separate from the chromophore assembly and effective to receive energy from the chromophore assembly, the terminal chromophore further effective to emit at least some of the received energy at a wavelength that is red-shifted from the at least one wavelength absorbed by the chromophore assembly.

In certain embodiments, the chromophore assembly comprises at least two chromophores that are effective to absorb at least some of the optical radiation. In other embodiments, the chromophore assembly comprises at least two chromophores that are effective to transfer energy to the terminal chromophore. In some examples, the chromophore assembly comprises a chromophore complex or a chromophore aggregate. In other examples, the chromophore assembly is selected from the group consisting of a chlorin, a phycobilosome, a porphyrin and a perylene bisimide dye. In additional examples, the substrate is a glass comprising a refractive index of at least 1.7. In some embodiments, the concentrator may comprise at least one wavelength selective mirror disposed on the substrate, the wavelength selective mirror configured to transmit incident light in a first wavelength range and to reflect incident light in a second wavelength range. In other examples, the concentrator may further comprise a polar matrix in which at least one of the chromophore assembly and the terminal chromophore is disposed. In certain examples, the concentrator may comprise a first photovoltaic cell optically coupled to the solar concentrator. In some examples, the concentrator may further comprise a second photovoltaic cell optically coupled to the solar concentrator, wherein the efficiency of the first and second photovoltaic cells is different.

In an additional aspect, a solar concentrator comprising a substrate and a film disposed on the substrate in a manner to receive at least some optical radiation, the film comprising a first and second chromophore is provided. In some examples, the first chromophore comprises an anti-Stokes material effective to absorb at least one wavelength of at least some of the optical radiation without substantial light emission of the absorbed optical radiation and further effective to transfer energy to the second chromophore by Förster energy transfer, the film further comprising a terminal chromophore effective to receive at least some transferred energy from the second chromophore and further effective to emit at least some of the received energy at a wavelength that is blue-shifted from the at least one wavelength absorbed by the anti-Stokes material.

In certain embodiments, the anti-Stokes material is selected from the group consisting of lanthanide complexes, thulium doped silicate glasses, europium complexes, terbium complexes, samarium complexes, dysprosium complexes, inorganic rare earth ions, inorganic rare earth crystals, bulk phosphor material, europium-activated yttriumoxysulphide, rare earth oxide nanocrystals, fluorides containing europium, chlorides containing europium, lanthanide phosphors, inorganic crystal lattices with trivalent rare earth dopants, yttriumoxysulphide activated with erbium and ytterbium, upconverting phosphor nanopowder from TAL Materials, Inc. (Ann Arbor, Mich.), anti-Stokes phosphors FCD-546-1, FCD-546-2, FCD-546-3, FCD-660-2, FCD-660-3 and FCD-660-4 from Luminophor JSC (Stavropol, Russia), anti-Stokes phosphor LPG-IR-3 from Platan R&DI (Moscow Region, Russia) and laser detection “anti-Stokes” phosphors PTIR545/UF, PTIR550/F and PTIR660/F from Phosphor Technology Ltd. (Stevenage, England). In other embodiments, the chromophore that receives energy from the anti-Stokes material is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, prradines, indocyanine green, styryls (Lambdachrome series), dioxazines, naphthalimides, thiazines, stilbenes, IR132, IR144, IR140, and Dayglo Sky Blue (D-286) and Columbia Blue (D-298). In additional embodiments, the chromophore that receives energy from the anti-Stokes material comprises a chromophore assembly. In some examples, the chromophore assembly is selected from the group consisting of a chlorin, a phycobilosome, a porphyrin, a cyanine dye and a perylene bisimide dye. In other examples, the substrate is a glass comprising a refractive index of at least 1.7. In additional examples, the concentrator may further comprise at least one wavelength selective minor disposed on the substrate, the wavelength selective mirror configured to transmit incident light in a first wavelength range and to reflect incident light in a second wavelength range. In other examples, the concentrator may further comprise a polar matrix in which at least one of the anti-Stokes material, the second chromophore or the terminal chromophore is disposed. In certain examples, the concentrator may further comprise a first photovoltaic cell optically coupled to the solar concentrator. In additional examples, the concentrator may comprise a second photovoltaic cell optically coupled to the solar concentrator, wherein the efficiency of the first and second photovoltaic cells is different.

In another aspect, a solar concentrator comprising a substrate and a film disposed on the substrate in a manner to receive at least some optical radiation, the film comprising a chromophore assembly which comprises at least a first chromophore and a second chromophore is provided. In certain examples, the first chromophore is effective to absorb at least some of the optical radiation and transfer at least some energy to the second chromophore. In some examples, the second chromophore is effective to emit at least some of the transferred energy at a wavelength that is red-shifted from a wavelength of optical radiation absorbed by the first chromophore, in which the first chromophore is present in the chromophore assembly at a concentration at least five times greater than the concentration of the second chromophore in the chromophore assembly.

In certain embodiments, the chromophore assembly comprises at least two chromophores that are effective to absorb at least some of the optical radiation. In other embodiments, the chromophore assembly comprises at least two chromophores that are effective to transfer energy to the second chromophore. In additional embodiments, the chromophore assembly comprises a chromophore complex or a chromophore aggregate. In other embodiments, the chromophore assembly is selected from the group consisting of a chlorin, a phycobilosome, a porphyrin, a cyanine dye and a perylene bisimide dye. In certain examples, the substrate is a glass comprising a refractive index of at least 1.7. In some examples, the concentrator may further comprise at least one wavelength selective minor disposed on the substrate, the wavelength selective mirror configured to transmit incident light in a first wavelength range and to reflect incident light in a second wavelength range. In one embodiment, the concentrator may further comprise a polar matrix in which at least one of the chromophore assembly is disposed. In other embodiments, the concentrator further comprises a first photovoltaic cell optically coupled to the solar concentrator. In certain examples, the concentrator may further comprise a second photovoltaic cell optically coupled to the solar concentrator, wherein the efficiency of the first and second photovoltaic cells is different.

In another aspect, a solar concentrator comprising a substrate, and a chromophore assembly disposed on or in the substrate in a manner to absorb at least some optical radiation, the chromophore assembly comprising a first chromophore effective to absorb at least some of the optical radiation within a first wavelength range and to transfer energy to a second chromophore of the chromophore assembly is provided. the second chromophore of the chromophore assembly effective to emit the transferred energy within a wavelength range that is red-shifted from the first wavelength range, in which the first and second wavelength ranges do not substantially overlap in wavelength.

In certain embodiments, the chromophore assembly comprises at least two chromophores that are effective to absorb at least some of the optical radiation. In other embodiments, the chromophore assembly comprises at least two chromophores that are effective to transfer energy to the terminal chromophore. In one example, the chromophore assembly comprises a chromophore complex or a chromophore aggregate. In another example, the chromophore assembly is selected from the group consisting of a chlorin, a phycobilosome, a porphyrin, a cyanine dye and a perylene bisimide dye. In some examples, the substrate is a glass comprising a refractive index of at least 1.7. In additional examples, the concentrator may further comprise at least one wavelength selective minor disposed on the substrate, the wavelength selective mirror configured to transmit incident light in a first wavelength range and to reflect incident light in a second wavelength range. In other examples, the concentrator may further comprise a polar matrix in which at least one chromophore of the chromophore assembly is disposed. In another example, the concentrator may comprise a first photovoltaic cell optically coupled to the solar concentrator. In some examples, the concentrator may further comprise a second photovoltaic cell optically coupled to the solar concentrator, wherein the efficiency of the first and second photovoltaic cells is different.

In another aspect, a solar concentrator comprising a substrate and a chromophore assembly disposed on or in the substrate in a manner to absorb at least some optical radiation, the chromophore assembly comprising a first chromophore effective to absorb at least some of the optical radiation within a first wavelength range and a second chromophore effective to receive energy from the first chromophore and to emit at least some of the received energy within a second wavelength range that is red-shifted from the first wavelength range is provided. In certain examples, the solar concentrator further comprises an effective amount of a red-shifting agent disposed on the substrate, the red-shifting agent effective to shift the second wavelength range to a higher wavelength range such that the first and second wavelength ranges do not substantially overlap in wavelength.

In certain embodiments, the chromophore assembly comprises at least two chromophores that are effective to absorb at least some of the optical radiation. In other embodiments, the chromophore assembly comprises at least two chromophores that are effective to transfer energy to the terminal chromophore. In certain embodiments, the chromophore assembly comprises a chromophore complex or a chromophore aggregate. In other embodiments, the chromophore assembly is selected from the group consisting of a chlorin, a phycobilosome, a porphyrin, a cyanine dye and a perylene bisimide dye. In additional embodiments, the substrate is a glass comprising a refractive index of at least 1.7. In further embodiments, the concentrator may comprise at least one wavelength selective minor disposed on the substrate, the wavelength selective mirror configured to transmit incident light in a first wavelength range and to reflect incident light in a second wavelength range. In additional examples, the concentrator may further comprise a polar matrix in which at least one of the chromophore assembly and the red-shifting agent is disposed. In other examples, the concentrator may further comprise a first photovoltaic cell optically coupled to the solar concentrator. In some examples, the concentrator may comprise a second photovoltaic cell optically coupled to the solar concentrator, wherein the efficiency of the first and second photovoltaic cells is different.

In an additional aspect, solar concentrator comprising a substrate, and a composition disposed on or in the substrate in a manner to absorb at least some optical radiation, the composition comprising a material selected from the group consisting of a chromophore assembly, an anti-Stokes material and combinations thereof is provided.

In certain embodiments, the chromophore assembly comprises at least two chromophores that are effective to absorb at least some of the optical radiation. In other embodiments, the chromophore assembly comprises at least two chromophores that are effective to transfer energy to a terminal chromophore. In additional embodiments, the chromophore assembly comprises a chromophore complex or a chromophore aggregate or both. In some embodiments, the chromophore assembly is selected from the group consisting of a chlorin, a phycobilosome, a porphyrin, a cyanine dye and a perylene bisimide dye. In other embodiment, the substrate is a glass comprising a refractive index of at least 1.7. In some embodiments, the concentrator may further comprise at least one wavelength selective mirror disposed on the substrate, the wavelength selective mirror configured to transmit incident light in a first wavelength range and to reflect incident light in a second wavelength range. In additional embodiments, the concentrator may comprise a polar matrix in which the chromophore assembly or the anti-Stokes material is disposed. In other embodiments, the concentrator may comprise a first photovoltaic cell optically coupled to the solar concentrator. In certain examples, the concentrator may comprise a second photovoltaic cell optically coupled to the solar concentrator, wherein the efficiency of the first and second photovoltaic cells is different.

In another aspect, a solar concentrator comprising a substrate, and a composition disposed on or in the substrate in a manner to absorb at least some optical radiation, the composition comprising a chromophore assembly effective to absorb at least some of the optical radiation within a first wavelength range is provided. In certain examples, the composition further comprises a second chromophore effective to receive energy from the chromophore assembly and to emit at least some of the absorbed optical radiation by phosphorescence within a second wavelength range that is red-shifted from the first wavelength range, in which the first and second wavelength ranges do not substantially overlap in wavelength.

In certain embodiments, the chromophore assembly comprises at least two chromophores that are effective to absorb at least some of the optical radiation. In certain examples, the chromophore assembly comprises at least two chromophores that are effective to transfer energy to the second chromophore. In other examples, the chromophore assembly comprises a chromophore complex or a chromophore aggregate or both. In some embodiments, the chromophore assembly is selected from the group consisting of a chlorin, a phycobilosome, a porphyrin, a cyanine dye and a perylene bisimide dye. In other embodiments, the substrate is a glass comprising a refractive index of at least 1.7. In additional embodiments, the concentrator may further comprise at least one wavelength selective minor disposed on the substrate, the wavelength selective minor configured to transmit incident light in a first wavelength range and to reflect incident light in a second wavelength range. In certain embodiments, the concentrator may further comprise a polar matrix in which at least one of the chromophore assembly and the second chromophore is disposed. In other embodiments, the concentrator may comprise a first photovoltaic cell optically coupled to the solar concentrator. In additional embodiments, the concentrator may comprise a second photovoltaic cell optically coupled to the solar concentrator, wherein the efficiency of the first and second photovoltaic cells is different.

In another aspect, a solar concentrator comprising a substrate and a composition disposed on or in the substrate in a manner to absorb at least some optical radiation, the composition comprising at least one chromophore assembly effective to absorb at least some of the optical radiation within a first wavelength range is disclosed. In certain examples, the composition further comprises a second chromophore effective to receive energy from the chromophore assembly and to emit the received energy by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength.

In certain embodiments, the chromophore assembly comprises at least two chromophores that are effective to absorb at least some of the optical radiation. In other embodiments, the chromophore assembly comprises at least two chromophores that are effective to transfer energy to the second chromophore. In some examples, the chromophore assembly comprises a chromophore complex or a chromophore aggregate or both. In other examples, the chromophore assembly is selected from the group consisting of a chlorin, a phycobilosome, a porphyrin, a cyanine dye and a perylene bisimide dye. In one example, the substrate is a glass comprising a refractive index of at least 1.7. In other examples, the concentrator may further comprise at least one wavelength selective mirror disposed on the substrate, the wavelength selective mirror configured to transmit incident light in a first wavelength range and to reflect incident light in a second wavelength range. In additional examples, the concentrator may comprise a polar matrix in which at least one of the chromophore assembly and the second chromophore is disposed. In some examples, the concentrator may further comprise a first photovoltaic cell optically coupled to the solar concentrator. In additional examples, the concentrator may comprise a second photovoltaic cell optically coupled to the solar concentrator, wherein the efficiency of the first and second photovoltaic cells is different.

In an additional aspect, a solar concentrator comprising a substrate and a composition disposed on or in the substrate in a manner to absorb at least some optical radiation, the composition comprising at least one anti-Stokes material effective to absorb at least some of the optical radiation within a first wavelength range, the composition further comprising a chromophore assembly effective to receive energy from the anti-Stokes material and to emit the received energy with in a second wavelength range that is blue-shifted from the first wavelength range is provided.

In certain embodiments, the composition further comprises an effective amount of a red-shifting agent complexed to the chromophore assembly to shift the second wavelength range to a higher wavelength range that has a maximum wavelength greater than the second wavelength range maximum but less than the first wavelength range maximum. In other examples, the chromophore assembly comprises at least two chromophores that are effective to transfer energy to the second chromophore. In additional examples, the chromophore assembly comprises a chromophore complex or a chromophore aggregate or both. In one example, the chromophore assembly is selected from the group consisting of a chlorin, a phycobilosome, a porphyrin, a cyanine dye and a perylene bisimide dye. In another example, the substrate is a glass comprising a refractive index of at least 1.7. In certain embodiments, the concentrator further comprise at least one wavelength selective minor disposed on the substrate, the wavelength selective mirror configured to transmit incident light in a first wavelength range and to reflect incident light in a second wavelength range. In one embodiment, the concentrator comprises a polar matrix in which at least one of the chromophore assembly and the anti-Stokes material is disposed. In other examples, the concentrator comprises a first photovoltaic cell optically coupled to the solar concentrator. In certain examples, the concentrator comprises a second photovoltaic cell optically coupled to the solar concentrator, wherein the efficiency of the first and second photovoltaic cells is different.

In an additional aspect, a solar concentrator comprising a substrate and a chromophore assembly disposed on or in the substrate, the chromophore assembly comprising a first chromophore and a second chromophore, wherein the first chromophore is oriented at an angle to increase absorption of light incident on the substrate and the second chromophore is oriented at an angle to increase light-trapping efficiency of the solar concentrator is disclosed. In certain examples, the first chromophore transfers energy to the second chromophore which emits light.

In certain embodiments, the chromophore assembly comprises at least two chromophores that are effective to absorb at least some of the optical radiation. In other embodiments, the chromophore assembly comprises at least two chromophores that are effective to transfer energy to the second chromophore. In some embodiments, the chromophore assembly comprises a chromophore complex or a chromophore aggregate or both. In other embodiments, the chromophore assembly is selected from the group consisting of a chlorin, a phycobilosome, a porphyrin and a perylene bisimide dye. In additional embodiments, the substrate is a glass comprising a refractive index of at least 1.7. In some examples, the concentrator may comprise at least one wavelength selective minor disposed on the substrate, the wavelength selective mirror configured to transmit incident light in a first wavelength range and to reflect incident light in a second wavelength range. In other examples, the concentrator may comprise a polar matrix in which the chromophore assembly is disposed. In additional examples, the concentrator may comprise a first photovoltaic cell optically coupled to the solar concentrator. In other examples, the concentrator may comprise a second photovoltaic cell optically coupled to the solar concentrator, wherein the efficiency of the first and second photovoltaic cells is different.

In another aspect, a tandem device comprising one or more of the solar concentrators described herein coupled to a thin film photovoltaic cell, wherein the solar concentrator and the thin film photovoltaic cell are each selected to have different bandgaps is provided

In an additional aspect, a device comprising a solar concentrator coupled to a portable electronic device is provided. In certain examples, the solar concentrator may also be coupled to a PV cell. In some examples, the portable electronic device is selected from the group consisting of a digital audio player, a mobile phone, a personal digital assistant, a portable computer, an image sensor, a camera, and a mobile environmental sensor.

Additional features, aspects, examples and embodiments are possible and will be recognized by the person of ordinary skill in the art, given the benefit of this disclosure.

### BRIEF DESCRIPTION OF THE FIGURES

Certain illustrative features, aspects, examples and embodiments are described below with reference to the figures in which:

FIG. 1 is an illustration of a solar concentrator, in accordance with certain examples;

FIG. 2 is an illustration of a chromophore assembly, in accordance with certain examples;

FIGS. 3A and 3B are schematics showing thin films disposed on a substrate, in accordance with certain examples;

FIG. 4 shows absorption and emission spectra for a chromophore, in accordance with certain examples;

FIG. 5 shows an absorption spectrum, a fluorescence emission spectrum and a phosphorescence emission spectrum, in accordance with certain examples;

FIG. 6 illustrate red-shifting of an emission spectrum, in accordance with certain examples;

FIG. 7 is a schematic of a substrate comprising wavelength selective minors disposed on opposite surfaces, in accordance with certain examples;

FIG. 8 is a schematic of a device that include a PV cell embedded in a waveguide, in accordance with certain examples;

FIGS. 9A and 9B are drawings of a LSC/PV cell assembly coupled to a portable device, in accordance with certain examples;

FIG. 10A is a photograph of a cast polyacrylamide film that incorporates intact phycobilisomes; the phycobilisomes consisted of fully coupled phycoerythrin, phycocyanin and allophycocyanin biliproteins.

FIG. 10 B is a schematic representation of the measurement set up used to determine the Optical Quantum Efficiency (OQE) of a phycobilisome film; the phycobilisome polyacrylamide film (nS=1.6) was cast upon a high index glass substrate (nS=1.7, Scott SF10 glass), and characterized in an integrating sphere to measure its edge emission as a function of excitation wavelength; the photoluminescence was detected by a Si photodetector mounted directly on the integrating sphere. Selective use of black tape and black marker is used to discriminate between face and edge emission;

FIG. 10C shows the optical quantum efficiency (dots) and normalized photoluminescence (solid line) of the acrylamide phycobilisome (PE-PC-APC) films; for comparison the absorption and photoluminescence spectra of the phycobilisome complexes in phosphate buffer are also plotted (dotted lines); the similarity with the cast waveguide data demonstrates that the optical properties of the phycobilisomes are well preserved in the solid state film.

FIG. 10D is a graph of the absorption and emission spectra of the phycobilisome complexes employed in the water-based LSCs; the green lines represent the spectra of the absorption and emission of the fully coupled phycobilisome with three types of biliproteins (PE-PC-APC); the absorption of the partially coupled PC-APC complexes and the fully decoupled PC-APC are identical (dashed red line and solid blue line respectively); the emission spectrum of the decoupled complex is dominated by the PC emission (solid blue), while the emission of the partially coupled complex results from the APC bilins (dashed red line); the Stokes shift is largest for the fully coupled complex consisting of PE-PC-APC, while the decoupled complex has the largest overlap between absorption and emission spectrum;

FIG. 11A is a schematic showing the performance of phycobilisome-based LSCs at higher optical concentrations is simulated by measuring the efficiency as a function of the path length of photons within the waveguide; an excitation beam was directed perpendicular to the LSC, creating a spot of about 1 mm², while the distance, d, between the spot and the solar cell was varied;

FIG. 11B is a graph showing the external quantum efficiency versus geometric gain, G, of the water-based LSCs employing fully coupled phycobilisomes with three types of biliproteins (PE-PC-APC) (green line), the partially coupled PC-APC phycobilisomes (red line), and the fully decoupled PC-APC phycobilisomes (blue line); the fully coupled complex has the best performance with geometric gain, reflecting its large Stokes shift, and hence reduced self-absorption losses;

FIG. 12 is a schematic of an embodiment of a tandem solar concentrator, in accordance with certain examples;

FIG. 13 is a graph showing predicted performance of the solar concentrator of FIG. 12, in accordance with certain examples;

FIG. 14 is a schematic showing a solar concentrator with a dessicant layer, in accordance with certain examples;

FIG. 15 is a schematic of another embodiment of a tandem solar concentrator, in accordance with certain examples;

FIG. 16 is a schematic of a packaged solar concentrator, in accordance with certain examples;

FIG. 17 is another schematic of a packaged solar concentrator, in accordance with certain examples;

FIG. 18A is a graph showing the self-absorption ratio in a DCJTB-based solar concentrator is S=80 (dotted lines); a larger self-absorption ratio of S=220 is obtained in a rubrene-based concentrator (solid lines), because the amount of DCJTB is reduced by a factor of three; its absorption is replaced by rubrene, which then transfers energy to DCJTB (see FIG. 18C); the inset of FIG. 18A shows the DCJTB chemical structure;

FIG. 18B is a graph showing phosphorescence emission (FIG. 18D) to reduce self-absorption; the self-absorption ratio in a Pt(TPBP)-based concentrator is S=500; the inset of FIG. 18B shows the Pt(TPBP) chemical structure;

FIG. 18C is a diagram showing energy transfer; near field dipole-dipole coupling can efficiently transfer energy between host and guest molecules; the guest molecule concentration can be less than 1%, significantly reducing self-absorption;

FIG. 18D is a diagram showing phosphoresence emission; spin orbit coupling in a phosphor increases the PL efficiency of the triplet state and the rate of intersystem crossing from singlet to triplet manifolds; the exchange splitting between singlet and triplet states is typically about 0.7 eV, significantly reducing self-absorption;

FIG. 19A shows the optical quantum efficiency (OQE) spectra of the DCJTB, rubrene and Pt(TPBP)-based single waveguide concentrators;

FIG. 19B shows the results from a tandem configuration where light is incident first on the rubrene-based OSC (blue); this filters the incident light incident on the second, minor-backed, Pt(TPBP)-based concentrator (green). The composite OQE is shown in red;

FIGS. 20A and 20B show graphs of concentrator efficiency and flux gain as a function of geometric gain; in FIG. 20A, with increasing G, photons must take a longer path to the edge-attached PV, increasing the probability of re-absorption; in FIG. 20B flux gain compares the electrical power output from the solar cell when attached to the concentrator relative to direct solar illumination; the flux gain increases with G, but reaches a maximum when the benefit of additional G is cancelled by self-absorption losses; near field energy transfer and phosphorescence substantially improve the flux gain relative to the DCJTB-based OSC; and

FIG. 21 shows an example of a tandem device, in accordance with certain examples.

It will be recognized by the person of ordinary skill in the art, given the benefit of this disclosure, that the dimensions of certain elements in the figures may have been enlarged, distorted or otherwise shown in a non-conventional manner to provide a more user-friendly description of the technology. In particular, the relative dimensions and thicknesses of the different components in the light emitting devices are not intended to be limited by those shown in the figures.

### DETAILED DESCRIPTION

Certain embodiments of the solar concentrators and devices using them that are disclosed herein provide significant advantages over existing devices including higher efficiencies, fewer components, and improved materials and improved optical properties. These and other advantages will be recognized by the person of ordinary skill in the art, given the benefit of this disclosure. Certain examples of the solar concentrators disclosed herein may be used with low cost solar cells that comprise amorphous or polycrystalline thin films. In addition, certain materials used in the solar concentrators described herein are effective to red-shift absorbed light or blue-shift absorbed light depending on the particular material or combination of materials present in the solar concentrator.

Certain materials or components are described herein as being disposed on or in another material or component. The term dispose is intended to be interchangeable with the term deposit and includes, but is not limited to, evaporation, co-evaporation, coating, painting, spraying, brushing, vapor deposition, casting, covalent association, non-covalent association, coordination or otherwise attachment, for at least some time, to a surface. Illustrative methods of disposing a selected component of the solar concentrators disclosed herein are described in more detail below.

In certain examples, the devices and methods disclosed herein are operative to absorb and/or transfer at least some energy. The phrase “at least some” is used herein in certain instances to indicate that not necessarily all of the energy incident on the substrate is absorbed, not necessarily all of the energy is transferred, or not necessarily the energy that is transferred is all emitted as light. Instead, a portion or fraction of the energy may be lost as heat or other non-radiative processes in the solar concentrators disclosed herein.

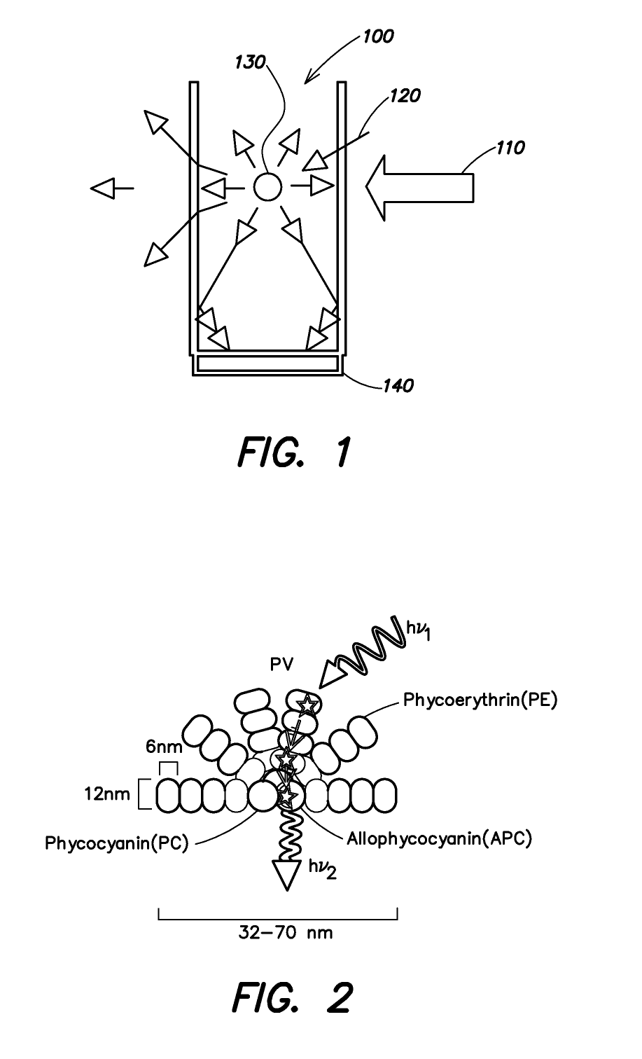

Luminescent solar concentrators (LSCs) are non-tracking concentrators that redirect solar radiation into simple slab waveguides. One illustration of an LSC is shown in FIG. 1. Light 110 incident on an LSC 100 is absorbed by a chromophore 130, re-emitted into a guided mode in the slab, and collected by a PV cell 140 mounted at the edge of the slab. The maximum optical concentration of an LSC can be limited by the wavelength shift between absorption and emission in the dye. Smestad et al., Solar Energy Materials 21, 99-111 (1990). Larger wavelength shifts reduce re-absorption of radiation already emitted into the LSC waveguide (see Batchelder et al., Applied Optics 18, 3090-3110 (1979); Batchelder et al, Applied Optics 20, 3733-3754 (1981)), and alleviate compounding losses if either the photoluminescence efficiency of the dye, η_{PL}, or the fraction of emitted light trapped in the waveguide, ηₜᵣₐₚ, is less than unity. Förster energy transfer has been used to mimic a four energy level laser design and minimize re-absorption losses in LSCs. See Currie et al., Science 321, 226-228 (2008). These devices use a low concentration of molecules that accept excited states from the surrounding LSC material. The low density of acceptor molecules takes over the light emission function of an LSC, shifting the emissive wavelength away from the peak of the LSC absorption. Energy is gathered by the acceptor molecules using Förster energy transfer. See Förster, T., Discussions of the Faraday Society 27, 7-17 (1959); Bailey et al., Solar Energy Materials and Solar Cells 91, 67-75 (2007). The bulk of the LSC can then be classified as donor molecules whose function is to absorb light and transfer the energy to the acceptors. To minimize re-absorption losses on the acceptor, the donor to acceptor ratio may be controlled. For example, it may be desirable to include as many donor molecules as possible within the energy harvesting range of every acceptor molecule, typically just 3-5 nm.

In certain examples, many methods can be used to control the intermolecular spacing. In one method, donor and acceptor molecules can be deposited in a thin film (˜1 μm) on a waveguide. This approach draws on organic semiconductor device technology and is known as an Organic Solar Concentrator (OSC). See Currie, Science 321, 226-228 (2008). The substrate is typically very transparent glass or plastic, and it has a higher refractive index than the film to prevent optical trapping in the organic layer. In another method, aggregates of dyes can be used where multiple donor molecules are physically coupled to relatively few acceptors. The second approach is compatible with the traditional LSC structure where dyes are cast at low density within a polymer matrix. Casting LSCs eliminates any need for expensive glass. The decoupled optical and electrical functions of LSCs and their attached solar cells, respectively, are analogous to the separate light collection and charge generation tasks in photosynthesis. See Blankenship, Molecular Mechanisms of Photosynthesis. Indeed, photosynthesis employs various light collection structures that may be used in LSCs.

Certain embodiments disclosed herein are directed to chromophore assemblies that include at least one species that can either, absorb light, transfer energy to another species, or emit light. In embodiments where the chromophore assemblies emit, but do not absorb light, an additional chromophore that absorbs incident light and can transfer energy to the chromophore assembly may be present in the LSC. In some examples, the chromophore assemblies may include at least one light absorber and at least one light emitter. In certain examples, the chromophore assemblies may include at least one light absorber, at least one donor molecule that receives energy from the at least one light absorber and at least one light emitter that receives energy from the at least one donor molecule. In certain embodiments, the light absorber and the donor molecule may not substantially emit light but instead can transfer their energy to the light emitter which effectively emits light at a desired wavelength and/or location, e.g., to a PV cell coupled to a solar concentrator comprising the chromophore assembly.

In some examples, the chromophore assemblies may be complexed or aggregated in that one or more chemical or physical interactions act to hold different components of the chromophore assembly at an effective distance from each other to permit energy transfer between the various species of the assembly. For example, the different chromophores may be complexed by being bonded to each other through one or more covalent bonds, may be associated with each other through one or more physical interactions (e.g., hydrogen bonding, van der Waals interactions, hydrophobic interactions, pi-pi interactions, salt bridges, etc.), or may otherwise form a higher ordered structure with two or more subunits having different optical properties.

In certain embodiments, the chromophore complex of the LSC may be an A:B complex where A is effective to absorb light and transfer at least some energy to B, which is effective as an terminal emitter. In other embodiments, the chromophore complex may be an A:B:C complex where A can absorb light and transfer at least some energy to B. The B chromophore is effective to transfer at least some energy to C, which emits the light to a PV cell coupled to the LSC including the A:B:C complex. In some examples, both A and B can transfer energy directly to C, for example, A and B may absorb light of different wavelengths and transfer that energy to C. C can emit the energy as light to a PV cell coupled to the LSC. In yet other examples, the chromophore complex may be and A:B:C:D complex where A is effective to absorb light and D is effective to emit light to a PV cell. Chromophores B and C may absorb light, receive transferred energy from A (or other chromophores) or may transfer energy to D. In some examples, a cascade may be created where A absorbs the light and energy transfer from A to B, B to C and C to D results in emission of light by D that is of a higher wavelength (red-shifted) compared to the wavelength of light that is absorbed by A.

In certain examples, the chromophore assembly may include multiple intermediate species that receive energy from another chromophore and/or transfer species to a different chromophore. In particular, depending on the exact number of components in the assembly, it is desirable in certain embodiments that one of the components absorb the light and one of the components emit the light. The remainder of the components may receive energy through energy transfer processes, such as Förster energy transfer processed discussed herein. The exact number of intermediate species present in the assembly is not critical and a plurality of intermediate species may be selected such that the absorbed energy is red-shifted by a desired wavelength range.

In certain embodiments, one or more species in the chromophore assembly can be a material that is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, prradines, indocyanine green, styryls (Lambdachrome series), dioxazines, naphthalimides, thiazines, stilbenes, IR132, IR144, IR140, Dayglo Sky Blue (D-286), Columbia Blue (D-298), and organometallic complexes of rare earth metals (such as europium, neodymium, and uranium, such as, for example, those described in C. Adachi, M. A. Baldo, S. R. Forrest, Journal of Applied Physics 87, 8049 (2000); K. Kuriki, Y. Koike, Y. Okamoto, Chemical Reviews 102, 2347 (2002); H. S. Wang, et al, Thin Solid Films 479, 216 (2005); Y. X. Ye, et al, Acta Physica Sinica 55, 6424 (2006).

In certain embodiments, the chromophore assembly may be arranged to have a central core about which other chromophores are arranged or oriented. In some examples, the chromophore within the central core may be selected to be the emitting chromophore and the absorbing chromophore may be positioned on the external surfaces of the chromophore complex. For example, a plurality of absorbing chromophores may be arranged around a central or single emitting chromophore. The absorbing chromophores may not necessarily completely surround or envelope the central chromophore but instead may be positioned around multiple sides, but not necessarily all sides, of the central chromophore. For example, three absorbing chromophores may be positioned along three sides of an emitting chromophore, assuming a square arrangement, with the fourth side remaining open and facing, for example, a PV cell that can receive light emission from the emitting chromophore. Many different arrangements and geometries are possible. In addition, a plurality of absorbing chromophores may be arranged around a plurality of emitting chromophores to provide desired optical properties. Additionally, a plurality of intermediate chromophores may be positioned between the absorbing chromophores and the emitting chromophores to transfer energy from the absorbing chromophores and to the emitting chromophores.

In certain examples, the exact ratio of the absorbing chromophore:emitting chromophore may vary. To increase the overall efficiency of the device, it may be desirable to have substantially more absorbing chromophores in the complex than emitting chromophores. In particular, the ratio of absorbing chromophore:emitting chromophore may be about 300:1 to about 1.5:1, more particularly about 200:1 to about 5:1, for example, about 100:1 to about 25:1. In configurations where an intermediate chromophore is present, the intermediate chromophore may also be present in a substantially larger amount than the emitting chromophore of the complex. For example, the intermediate chromophore:emitting chromophore ratio may be about 300:1 to about 1.5:1, more particularly about 200:1 to about 5:1, for example, about 100:1 to about 25:1 The ratio of absorbing chromophore:intermediate chromophore(s) is not critical and may be less than 1:1, 1:1, greater than 1:1, between 1:1 and 2:1, between 1:1 and 1:2, between 1:1 and 3:1 or between 1:1 and 1:3. Other suitable ratios will be selected by the person of ordinary skill in the art, given the benefit of this disclosure and depending on the desired optical properties of the LSC.

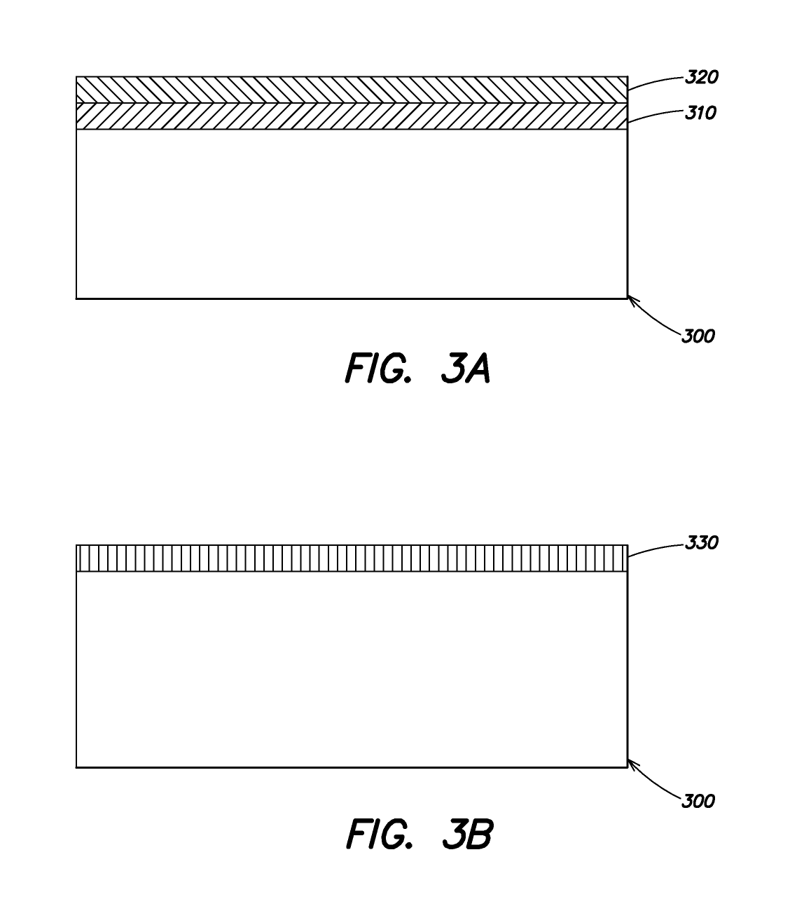

In certain embodiments, the chromophore complex may be a photosynthetic complex that is present in one or more microorganisms such as, for example, algae, bacteria and the like. For example, phycobilisomes are large water soluble pigment-protein complexes that function as light harvesting devices in red algae and cyanobacteria. They are capable of absorbing light over a broad range of the visible spectrum and efficiently concentrating this captured energy at the photosynthetic reaction center. The main components of phycobilisomes are phycobiliproteins, which serve as scaffolding for covalently bound, linear tetrapyrrole chromophores called bilins. See Glazer, A. N., Methods in enzymology 167, 291 (1988). The chromophores are arranged through self-assembly in cascading Förster energy transfer pathways that couple short wavelength chromophores at the extremities of the complex to long wavelength chromophores at the core of the complex. The phycobilisome core is composed of allophycocyanin (APC) (see FIG. 2) containing approximately 72 chromophores (phycocyanobilin) that absorb at λₘₐₓ=650 nm. Depending on the organism, 4-6 phycocyanin (PC) radial rods are attached to the core, each rod contains approximately 18 chromophores (phycocyanobilin) absorbing at λₘₐₓ=620 nm. Finally, in some organisms, the PC rods are capped by additional rod structures containing phycoerythrin (PE) with approximately 34 chromophores (phycoerythrobilin or phycourobilin) that absorb at either λₘₐₓ=545 nm or λₘₐₓ=490 nm. The total number of bilins per phycobilisome is highly variable between different species and even within a species under different growth conditions. See MacColl, R. & Guard-Friar, D. Phycobiliproteins (CRC Press, Boca Raton, 1987). But a typical estimate for the ratio of chromophores in PE, PC and APC is 408:108:72, i.e. the number of donor chromophores in PE and PC is much larger than the number of acceptor chromophores in APC, demonstrating that phycobilisomes can be used to reduce self absorption in LSCs. See Choi et al., Journal of Nanoscience and Nanotechnology 6, 3526-3531 (2006). The quantum efficiency of energy transfer within the complex typically exceeds 95%. See Grabowski et al., Photochemistry and Photobiology 28, 47-54 (1978). But when decoupled, energy transfer is prevented and the chromophores emit light. The photoluminescent (PL) efficiency varies between η_{PL}=98% for PE, η_{PL}=51% for PC, and η_{PL}=68% for APC. In other examples, the chromophore complex may be a photosynthetic complex that is present in one or more plants. In other embodiments, the chromophore complex may be a derivative or analog of a photosynthetic complex.

In certain other embodiments, the chromophore assemblies may take the form of an aggregate that can be used in an LSC to increase the overall efficiency of a device that includes a PV cell. In certain embodiments, J-aggregates (also known as Scheibe aggregates) may be used as the chromophore assemblies in a LSC. J-aggregates are specific organic dye assemblies characterized by a narrow and intense absorption band that shows a bathochromic shift as compared to the relevant monomer band. This J-band, which appears at lower transition energies than the absorption spectrum of the dye at low concentrations, is due to the transition of excitons delocalized over an aggregate by intermolecular dipole interaction. In J-aggregates, the transition moments of individual monomers are typically aligned parallel to a line joining their centers (an end-to-end arrangement). J-aggregates can form at high dye concentrations to provide aggregated chromophores whose optical properties are improved compared to the non-aggregated dye. In particular, J-aggregates can have emission wavelengths that are red-shifted when compared to the emission wavelengths of non-aggregated dyes. J-aggregate formation may occur spontaneously at high concentrations through intermolecular interactions of the dye molecules. J-aggregates can form microstructures including, but not limited to, disc-like structures, rod-like structures and other three-dimensional structures. The components of the dyes may be selected to favor J-aggregate formation. For example, J-aggregate formation can be favored using dyes having bulky mesosubstituents, as these substituents can result in tighter packing of the molecules in the aggregate.

In certain embodiments, the J-aggregates used in the chromophore assemblies may be dimers, trimers or higher ordered structures or structures which include repeating monomeric units. The J-aggregates may be uniform in that they are composed of a single dye molecule or the J-aggregates may be mixed in that they include two or more different dye molecules. The J-aggregates may be spin coated or deposited in thin films on a substrate to provide an LSC. As discussed herein, films of J-aggregates can provide improved optical properties when compared to corresponding non-aggregated dye films.

In certain examples, the J-aggregates may be produced using a chlorin, a porphyrin, a cyanine dye, a perylene bisimide dye or the like. In embodiments where the chlorin includes a magnesium ion, a chlorophyll is formed. Examples of chlorins include, but are not limited to, metallochlorins (for instance, Zn or Mg), bis(metallochlorins), and the aggregated chlorins in chlorosomal antennas of green bacteria such as Chlroroflexus aurantiacus. Illustrative examples of porphyrins include, but are not limited to, meso-tetrakis(p-sulfonatophenyl)porphyrin, tetraphenylporphinesulfonate, tetracarboxyphenyl-porphine, tetra(N-methyltetrapryidyl)porphine, uroprophyrin I, metallouroporphyrins, urohemin, picket fence porphyrins, 4,0-meso-tetrakis(2-hexanamidophenyl)porphyrin, tetraaryl substituted porphyrins, (5,10,15,20-tetrakis [4-(1-octyloxy)phenyl)]prophinato(copper-II), tetraphenyl porphyrins, tetrakis-(4-(hexadecyloxy)phenyl)porphyrin, tris(4-hexadecycloxy)-phenyl)(4-methylpyridinium)porphyrin tosylate, meso-diphenylbis(N-methyl-4-pyridyl)-porphyrin, tetraphenylporphine, and tetra(p-N-methylpryidyl)porphine. Illustrative types of cyanine dyes that can form J-aggregates include, but are not limited to, (5,6-dichloro-2-[3-[5,6-dichloro-1-ethyl-3-(3-sulfopropyl)-2(3H)-benzimidazolidene]-1-propenyll-1-ethyl-3-(3-sulfopropyl), quino-2-monomethine, psuedoisocyanine, 1,1′-diethyl-4,4′-cyanine and 1,1′-diethyl-2,2′-cyanine. Illustrative types of imides that may be used as J-aggregates include, but are not limited to, perylene bisimides, naphthalenemonoimide, terrylene, perylene monoimide, and other rylenes. Other materials that may be used as J-aggregates include, but are not limited to polymethines, squarains, squaric acids, rotaxanes, xanthenes, and stilbenes.

In other examples, aggregates other than J-aggregates, or in addition to J-aggregates, can be used in the LSC's described herein. For example, H-aggregates may be used with, or in place of J-aggregates. H-aggregates may be particularly desirable to absorb blue-shifted light, as compared to the absorption wavelength of the monomer. This blue-shifting of the absorption wavelength in H-aggregates is believed to occur due to the transition moment alignment in H-aggregates, where the transition moments of individual monomers are aligned parallel to each other but are perpendicular to a line joining their centers (a face-to-face arrangement). Illustrative H-aggregates include those formed from stilbenes, stilbazolium amphiphiles, perylene bisimides, squaraines, squaric acids, polymethines, xanthenes, and derivatives and analogs thereof. Specific materials that can form H-aggregates include, but are not limited to, (5,6-dichloro-2-[3-[5,6-dichloro-1-ethyl-3-(3-sulfopropyl)-2(3H)-benzimidazolidene]-1-propenyll-1-ethyl-3-(3-sulfopropyl), quino-2-monomethine, psuedoisocyanine, 1,1′-diethyl-4,4′-cyanine and 1,1′-diethyl-2,2′-cyanine, tetraphenylporphinesulfonate, tetracarboxyphenyl-porphine, tetra(N-methyltetrapryidyl)porphine, meso-tetrakis(p-sulfonatophenyl)porphyrin uroprophyrin I, metallouroporphyrins, urohemin, picket fence porphyrins, 4,0-meso-tetrakis(2-hexanamidophenyl)porphyrin, tetraaryl substituted porphyrins, (5,10,15,20-tetrakis [4-(1-octyloxy)phenyl)]prophinato(copper-II), tetraphenyl porphyrins, tetrakis-(4-(hexadecyloxy)phenyl)porphyrin, meso-diphenylbis(N-methyl-4-pyridyl)-porphyrin, tetraphenylporphine, tris(4-hexadecycloxy)-phenyl)(4-methylpyridinium)porphyrin tosylate, and tetra(p-N-methylpryidyl)Porphine, naphthalenemonoimide, terrylene, and perylene monoimide.

In certain examples, the materials may convert from J-aggregates to H-aggregates depending on the physical environment the dye monomers are in and whether or not hydrogen bonding or other interactions favor one aggregate form over the other. For example, J-aggregates that include nitrogen, oxygen or fluorine heteroatoms may hydrogen bond with adjacent monomers to convert the J-aggregate into an H-aggregate or vice versa depending on the overall structure and physical properties of the dye molecule.

In certain embodiments, the LSC described herein may include an anti-Stokes material, which may be used in combination with one or more other chromophores including, but not limited to, the chromophore assemblies described herein. Anti-Stokes materials absorb light and re-emit the light at higher energies. For example, an anti-Stokes material can absorb infrared radiation and emit radiation at a shorter wavelength in the visible region. This result may be particularly advantageous as much of the solar power reaching the earth is in the infrared spectrum. Most materials in solar cells do not absorb infrared light to any usable degree. LSCs that use organic semiconductors do not absorb infrared light. In addition, for deep infrared light, absorbed light can be converted to charge only at low efficiencies, due to the existence of many degradation pathways for low-energy excitations.

In certain embodiments, the anti-Stokes material may be used to receive energy from another chromophore and emit light to a PV cell. In another embodiment, the anti-Stokes material may absorb light and transfer energy to another chromophore which itself emits light. In particular, when an anti-Stokes emitter with low photoluminescence efficiency is used in combination with a terminal dye with higher photoluminescence efficiency, then the light initially absorbed by the anti-Stokes materials will be emitted by the more efficiency terminal chromophore, increasing the overall efficiency of the LSC. For example, a typical LSC does not efficiently absorb infrared light. When an anti-Stokes emitter is used in an LSC, however, infrared light may be captured by the anti-Stokes emitter, and energy may be transferred to a terminal chromophore that can emit light to a PV cell. This arrangement permits concentration of the captured light and provides more efficient power conversion.

In certain examples, the anti-Stokes materials may be used in combination with one or more of the chromophore assemblies discussed herein. In particular, the anti-Stokes materials may be used in combination with J-aggregates, H-aggregates, chromophore assemblies and the like. In some examples, one or more additional chromophores that can either receive energy through Förster energy transfer, or transfer energy to another chromophore through Förster energy transfer, may also be used. A particularly advantageous combination is an anti-Stokes emitter in combination with a terminal dye. Illustrative anti-Stokes materials that may be used alone or in any combination include, but are not limited to, lanthanide complexes, thulium doped silicate glasses, europium complexes, terbium complexes, samarium complexes, dysprosium complexes, inorganic rare earth ions, inorganic rare earth crystals, bulk phosphor material, europium-activated yttriumoxysulphide, rare earth oxide nanocrystals, fluorides containing europium, chlorides containing europium, lanthanide phosphors, inorganic crystal lattice with trivalent rare earth dopants, yttriumoxysulphide activated with erbium and ytterbium, upconverting phosphor nanopowder from TAL Materials, Inc. (Ann Arbor, Mich.), anti-Stokes phosphors FCD-546-1, FCD-546-2, FCD-546-3, FCD-660-2, FCD-660-3 and FCD-660-4 from Luminophor JSC (Stavropol, Russia), anti-Stokes phosphor LPG-IR-3 from Platan R&DI (Moscow Region, Russia) and laser detection “anti-Stokes” phosphors PTIR545/UF, PTIR550/F and PTIR660/F from Phosphor Technology Ltd. (Stevenage, England). Those anti-Stokes materials that have one or more absorption bands in the IR (either near infrared (0.75-1.4 μm), short wavelength infrared (1.4-3 μm), mid-wavelength infrared (3-8 μm), long-wavelength infrared (8-15 μm), far infrared (15-1,000 μm)) are particularly suited for use in the LSCs disclosed herein. In other examples, an anti-Stokes material that has at least one absorption band in the IR-A (700 nm-1400 nm), IR-B (1400 nm-3000 nm) or IR-C (3000 nm-1 mm) may be used in the LSCs described herein. In yet other examples, the anti-Stokes materials may be selected to have an absorption band within the commonly understood telecommunication bands. For example, an O-material has an absorption band in the O-band (1260-1360 nm), an E-material has an absorption band in the E-band (1360-1460 nm), an S-material has an absorption band in the S-band (1460-1530 nm), a C-material has an absorption band in the C-band (1530-1565 nm), a L-material has an absorption band in the L-band (1565-1625 nm) and a U-material has an absorption band in the U-band (1625-1675 nm). As discussed above, the nature of the anti-Stokes material can result in shifting of emission to a shorter wavelength (higher energy) than the wavelength that is absorbed by the O-, E-, S-, C-, L- and U-materials.

In certain embodiments, the terminal dye that is used in combination with the anti-Stokes material may be, for example, rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, prradines, indocyanine green, styryls (Lambdachrome series), dioxazines, naphthalimides, thiazines, stilbenes, IR132, IR144, IR140, and Dayglo Sky Blue (D-286) and Columbia Blue (D-298). Other suitable dyes may be used that are effective to receive energy from the anti-Stokes material and emit at least a portion of that energy as light.

In certain embodiments, the anti-Stokes material may be present at least five times, ten times or more as compared to the amount or concentration of the emitting chromophore present in the LSC. For example, the anti-Stokes material may be present in larger quantities to increase absorption of light, and the emitting chromophore can be present in lower amounts to reduce the likelihood of self-absorption or quenching. The exact amount of the anti-Stokes material and the emitting chromophore that may be present can vary depending on the desired optical properties of the LSC. In certain examples, the ratio of the anti-Stokes material:emitting chromophore may be from 300:1 to about 1.5:1, more particularly about 200:1 to about 5:1, for example, about 100:1 to about 25:1.

The efficiency limit of a single guide concentrator is set by the quantum defect, or difference in energy between absorption and emission of the active chromophores. Following absorption, a luminescent chromophore may emit a single photon and the energy difference between the absorbed and emitted photons is converted to thermal energy not available for conversion at a solar cell. The efficiency limit can be increased through the use of exciton fission materials, where the absorption of a single photon can result in multiple excitons on adjacent chromophores. The exciton fission process occur when a materials which possesses multiple exciton states where the allowed states (those which result in singlet excitons) is approximately 175% or more energy then excitons states which have disallowed states (triplet excitons). Following optical absorption which populates the singlet state, such materials may spontaneously split the singlet exciton to two triplet excitons on neighboring chromophores, one of which may include the original chromophore which originated the singlet exciton.

Luminescence from triplet excitons are disallowed, so the photoluminescence efficiency of triplet states is typically near zero. However, the photoluminescence efficiency can be increased in the presence of an intersystem mixing process, such as spin-orbit coupling. This process may occur on a single phosphor chromophore that possesses a mechanism for spin-orbit coupling via a heavy metal atom (such as those described in commonly-owned U.S. patent application Ser. No. 12/353,459 filed Jan. 14, 2009, for example), or through Förster energy transfer to a neighboring chromophore where the transition is allowed. The exciton fission process can occur with approximately 100% efficiency in tetracene, rubrene, and pentacene, because these chromophores naturally meet the energy matching criteria. To concentrate light which electrical conversion will occur at silicon photovoltaic cells, tetracene is an attractive chromophore for use in luminescent solar concentrators. Its triplet state falls within the spectral band close to the silicon bandgap, and exciton fission is only weakly endothermic. The singlet and triplet exciton energies are 2.25 eV (λ=550 nm) and 1.27 eV (λ=975 nm), respectively. Exciton fission has been previously employed in high efficiency photodetectors, where exciton fission on pentacene resulted in an increase in the quantum efficiency of charge generation to 147%, as described in J. Lee, P. Jadhav, M. A. Baldo, Applied Physics Letters 95, 033301 (2009).

In certain embodiments, the LSC described herein may include an exciton fission material, which may be used in combination with one or more other chromophores including, but not limited to, the chromophore assemblies described herein. Exciton fission materials absorb photons and may re-emit two or more photons at lower energies. For example, an exciton fission material can absorb ultraviolet or violet radiation and emit radiation at a longer wavelength in the red or infrared region.

In another embodiment, the exciton fission material may absorb light and transfer energy to another chromophore which itself emits light. In particular, when an exciton fission material with low photoluminescence efficiency is used in combination with a terminal dye with higher photoluminescence efficiency, then the efficiency of the terminal chromophore may effectively emit light first absorbed by the exciton efficiency material with high efficiency, effective to increase the overall efficiency of the LSC. For example, a typical LSC emits a single photon following absorption of ultraviolet or visible light. When an exciton fission emitter is used in an LSC, however, ultraviolet or visible light may be captured by the exciton fission emitter, and energy may be transferred to two or more terminal chromophores that can emit light to a PV cell. This arrangement permits concentration of the captured light and provides more efficient power conversion.

In certain embodiments, the exciton fission material is selected from the group consisting of the polyacenes, tetracene, pentacene, and rubrene. In other embodiments, the chromophore that receives energy from the exciton fission material is selected from the group consisting of rare earth phosphors, ytterbium, neodymium, rare earth organo-metallic complexes, or quantum dots. In certain examples, the LSCs described herein are operative to separate the photovoltaic functions of light collection and charge separation. For example, light may be gathered by an inexpensive collector that comprises one or more light absorbing materials such as, for example, those described herein. The collected light may be focused onto a smaller area of a photovoltaic (PV) cell. The ratio of the area of the collector to the area of the PV cell is known as the geometric concentration factor, G. One attraction of the light concentrator approach is that the complexity of a large area solar cell is replaced by a simple optical collector. PV cells are still used, but large G values of a light concentrator coupled to a PV cell can reduce the PV cost, potentially lowering the overall cost per watt of generated power. A typical LSC, as shown in FIG. 1, comprises a substrate that includes one or more light absorbing materials disposed on or in the substrate. The substrate can be optically coupled to at least one solar cell (also referred to as PV cell in certain instances herein) at the edge of the substrate. Solar radiation is incident on the substrate where it is absorbed by one or more of the chromophores described herein or other suitable chromophores that can be used in the LSC. Energy may be re-radiated within the substrate, and the re-radiated energy may be guided toward the edge for collection by the PV cells. One advantage of using LSC's over PV concentration systems, e.g., mirrors, lenses, dishes and the like, is that very high concentration factors may be achieved without cooling or mechanical tracking.

In certain embodiments, the solar concentrators disclosed herein may include a substrate that is operative to trap and/or guide light. That is, the substrate itself may be configured to improve the overall efficiency in addition to the efficiency improvement gained using the chromophore assemblies and/or anti-Stokes materials described herein. The terms substrate and waveguide may be interchanged for the purposes of this disclosure. Such trapped light may be directed to or otherwise coupled to a PV cell such that the light may be converted into a current by the PV cell. The substrate need not be in direct sunlight but instead, may be used to receive direct, indirect and diffuse solar radiation. In some examples as discussed below, the substrate may be selected such that one or more chromophores, chromophore assemblies or anti-Stokes materials may be disposed in or on the substrate or the substrate may be impregnated with the chromophore, chromophore assembly or anti-Stokes material. The chromophore may be any substance that can absorb and/or emit light of a desired or selected wavelength. In certain examples, a chromophore assembly or an anti-Stokes material may be used, either alone or in combination with at least one additional chromophore in an LSC. Any material that can receive a chromophore may be used in the substrates of the solar concentrators described herein.

In certain examples, the substrate may include a material whose refractive index is greater than 1.7. Illustrative materials for use in the substrates of the solar concentrators disclosed herein include, but are not limited to, polymethylmethyacrylate (PMMA), glass, lead-doped glass, lead-doped plastics, aluminum oxide, polycarbonate, halide-chalcogenide glasses, titania-doped glass, titania-doped plastics, zirconia-doped glass, zirconia-doped plastics, alkaline metal oxide-doped glass, alkaline metal oxide-doped plastics, barium oxide-doped glass, barium-doped plastics, zinc oxide-doped glass, and zinc oxide-doped plastics. In certain examples, the dimensions of the substrate may vary depending on the desired efficiency, overall size of the concentrator and the like. In particular, the substrate may be thick enough such that a sufficient amount of light may be trapped, e.g., 70-80% or more of the quanta of radiation (i.e., 7-80% of the incident photons). In certain examples, the thickness of the substrate may vary from about 1 mm to about 4 mm, e.g., about 1.5 mm to about 3 mm. The overall length and width of the substrate may vary depending on its intended use, and in certain examples, the substrate may be about 10 cm to about 300 cm wide by about 10 cm to about 300 cm long. The exact shape of the substrate may also vary depending on its intended use environment. In some examples, the substrate may be planar or generally planar, whereas in other examples, the substrate may be non-planar. In certain examples, opposite surfaces of the substrate may be substantially parallel, whereas in other examples opposite surfaces may be diverging or converging. For example, the top and bottom surfaces may each be sloped such that the width of the substrate at one end is less than the width of the substrate at an opposite end.

In certain embodiments, the solar concentrators disclosed herein may be produced using a high refractive index material. The term “high refractive index” refers to a material having a refractive index of at least 1.7. By increasing the refractive index of the substrate, the light trapping efficiency of the solar concentrator may be increased. Illustrative high refractive index materials suitable for use in the solar concentrators disclosed herein include, but are not limited to, high index glasses such as lead-doped glass, aluminum oxide, halide-chalcogenide glasses, titania-doped glass, zirconia-doped glass, alkaline metal oxide-doped glass, barium oxide-doped glass, zinc oxide-doped glass, and other materials such as, for example, lead-doped plastics, barium-doped plastics, alkaline metal oxide-doped plastics, titania-doped plastics, zirconia-doped plastics, and zinc oxide-doped plastics. In some examples any material whose light trapping efficiency is at least 80% of the quanta of radiation or more may be used as a high refractive index substrate.

In certain examples, first and second chromophores may be disposed on or in a substrate and may be selected to exploit Förster near field energy transfer. One of the first and second chromophores may be a chromophore assembly or an anti-Stokes material as described herein. In some examples, both the first and second chromophores may be included with a chromophore assembly or one of the chromophores may be within a chromophore assembly and the other chromophore may be separate from the chromophore assembly. Förster near field energy transfer couples the transition dipoles of neighboring molecules and may be exploited to couple one chromophore with a short wavelength absorption to a second chromophore with a longer wavelength absorption. For example, the concentrator may be configured with closely spaced chromophores. As used herein, the term “closely-spaced” refers to positioning or arranging the chromophores adjacent to or sufficiently close to each other such that Förster near field energy transfer may occur from one of the chromophores to the other chromophore. Such transfer of energy generally occurs without emission of a photon and results in an energy shift between absorption and emission. Where an anti-Stokes material is used as one of the chromophores, the second chromophore may be selected such that Förster energy transfer occurs at higher energies than the light absorbed by the anti-Stokes material. Such energy transfer can result in emission of light at shorter wavelengths, e.g., blue-shifted, as compared to the wavelength of light absorbed by the anti-Stokes material.

In certain examples, at least first and second closely spaced chromophores may be disposed on or in the substrate in a manner to receive optical radiation. While reference is made herein to “first” and “second” chromophores, the first chromophore or the second chromophore or both may include, or be part of, a chromophore assembly such as a chromophore complex or an aggregate or may be one or more anti-Stokes materials. For convenience purposes only, these assemblies and materials are described in certain instances below using the singular term “chromophore.” The first chromophore may be effective to absorb at least one wavelength of the optical radiation and may also be effective to transfer energy by Förster energy transfer to the second chromophore. The second chromophore may be effective to emit the transferred energy at a wavelength that is red-shifted from the wavelength absorbed by the first chromophore. The use of two chromophores as described above may improve the overall efficiency of the solar concentrator by reducing self-absorptions. In one embodiment, the first and second chromophores may be in a chromophore assembly such that inclusion of the chromophore assembly in or on the substrate of the LSC can provide for both absorption and emission functions of the LSC. In other embodiments, an anti-Stokes material may be included in or on the substrate, and a dye or other suitable material may be used as the second chromophore to receive energy from the anti-Stokes material and emit at least some of that energy as light.

In one illustration, the first chromophore may be tris-(8-hydroxylquinoline) aluminum (AlQ3) or rubrene, or both, and the second chromophore, which emits light, may be a chromophore assembly. Both of tris-(8-hydroxylquinoline) aluminum or rubrene are fluorescent at high concentrations and have suitable electronic properties that permit energy transfer to chromophore assemblies including, but not limited to, chlorins, phycobilisomes or other complexes or aggregates.

In some examples, the chromophore may be a perylene or terrylene diimide molecule or a molecule having at least one perylene or terrylene diimide unit in it, e.g., a derivatized perylene or terrylene diimide chromophore, which may form aggregates at high concentrations. For example, the first chromophore may be tris-(8-hydroxylquinoline) aluminum (AlQ3) or rubrene, or both, and the second chromophore may be a J-aggregate, such as, for example, J-aggregates formed from a cyanine dye or a perylene bisimide. In other embodiments, the first chromophore may be an anti-Stokes material and the second chromophore may be DCM or other dye material that can receive energy from the anti-Stokes material and emit that energy to a PV cell. In some embodiments, the emitting dyes that may receive energy from the anti-Stokes materials may be of the class consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, prradines, indocyanine green, styryls (Lambdachrome series), dioxazines, naphthalimides, thiazines, stilbenes, IR132, IR144, IR140, and Dayglo Sky Blue (D-286) and Columbia Blue (D-298).

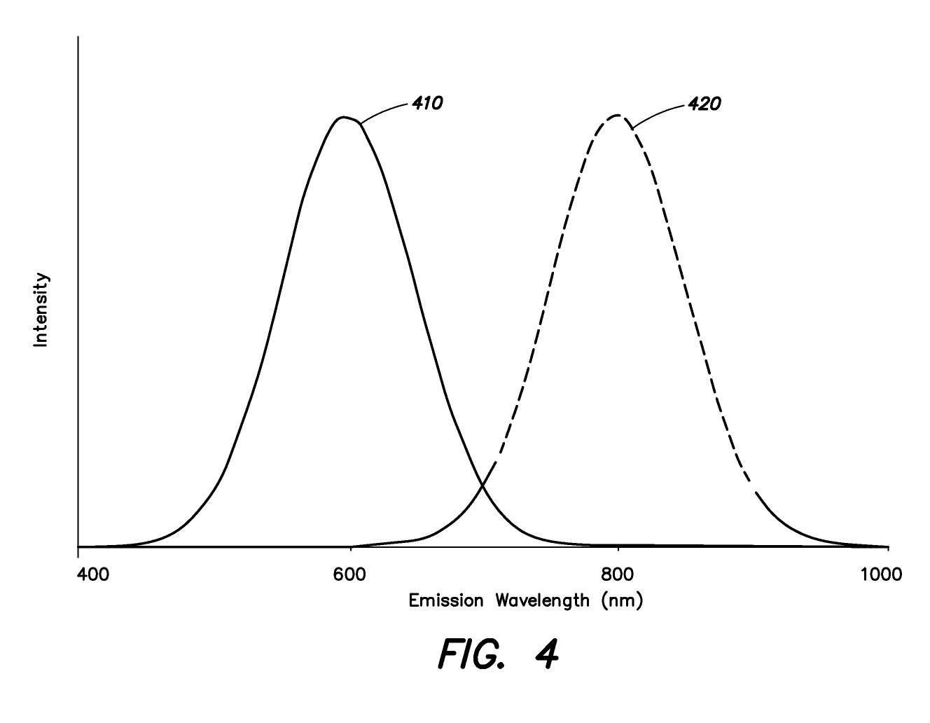

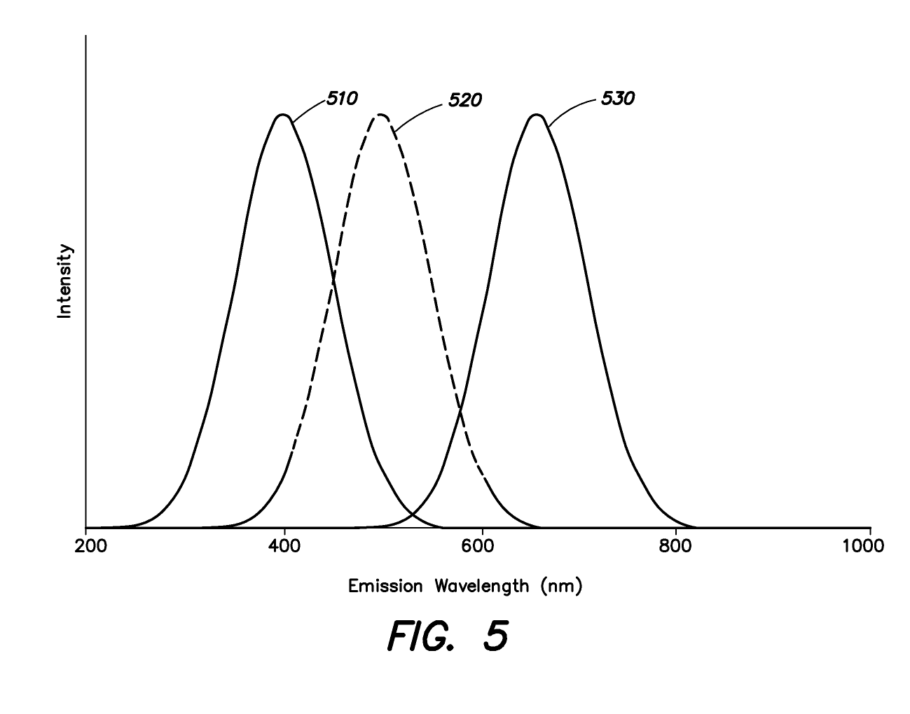

In certain examples, to take advantage of the Förster energy transfer, which is typically a short range interaction occurring over 3-4 nm, the chromophores, chromophore assemblies and/or anti-Stokes materials, and any other chromophores that are selected for use, may be disposed in one or more thin films on a substrate. For example and referring to FIG. 3A, a thin film of a first chromophore 310 may be disposed on a substrate 300. A thin film of a second chromophore 320 may be disposed on the first chromophore 310. In an alternative configuration as shown in FIG. 3B, the chromophores may be mixed together and disposed simultaneously on the substrate 300 to provide a thin film 330 or may be co-evaporated on the substrate 300 to provide a thin film 330. The exact thickness of the thin film may vary, and in certain examples, the film is about 0.5 microns to about 20 microns, more particularly about 1 micron to about 10 microns. In some examples, the Förster energy transfer ensures red-shifting of the emission. Such red-shifting provides the advantage of reducing the emission spectrum overlap with the absorption spectrum, which could decrease the overall efficiency of the solar concentrator. For example and referring to FIG. 4, the Förster energy transfer to a chromophore assembly, or within a chromophore assembly, can result in shifting of the light emission to a higher wavelength 420 as compared to the wavelength emission 410 in the absence of Förster energy transfer. Such shifting reduces the overlap between the absorption and emission spectra thus reducing the likelihood of reabsorption.

In embodiments where an anti-Stokes material is used, blue-shifting may occur such that the light emitted by a terminal chromophore has a wavelength that is less than the light absorbed by the anti-Stokes material. For example, the anti-Stokes material may absorb light in one infrared region and transfer that energy such that light is emitted in the infrared at a wavelength less than the infrared wavelength absorbed. The anti-Stokes material may absorb light in one infrared region and transfer that energy such that light is emitted in the visible range at a wavelength less than the infrared wavelength absorbed. The anti-Stokes material may be used in combination with intermediate chromophores, which themselves may be anti-Stokes materials, to provide a cascade mechanism to reduce the wavelength of the emitted light. The combination of these materials may be deposited in a desired order in a thin film on the substrate as described herein. For example, thin films including bulk assemblies or complexes dispersed in them may be used and deposited, for example, using extrusion, casting, thermoforming or other suitable techniques.

In accordance with certain examples, to favor Förster energy transfer, it may be desirable to incorporate different amounts of the various chromophores into the solar concentrators. For example, it may be desirable to use substantially lower amounts of the chromophore that emits the light and higher amounts of the chromophore that transfers the energy by Förster energy transfer. In some examples, at least five times more of the chromophore absorbing the optical radiation, e.g., the solar radiation, is present as compared to the amount of light emitting chromophore that is present. In other examples, at least ten times more of the chromophore absorbing the optical radiation is present as compared to the amount of light emitting chromophore that is present. Suitable ratios of light absorbing chromophores to light emitting chromophores will be readily selected by the person of ordinary skill in the art, given the benefit of this disclosure. For example, illustrative ratios where chromophore assemblies and anti-Stokes material are used are described herein.

In accordance with certain examples, it may be desirable to use multiple different chromophores to absorb the optical radiation and a single terminal chromophore to emit light to the PV cell. The terminal chromophore may be disposed adjacent to or near the PV cell such that light emission occurs in proximity to the PV cell. For example, two or more chromophores that absorb light at different wavelengths may be disposed on or in the substrate. Each of the chromophores may be configured such that they transfer energy to one or more terminal chromophores that emit light, e.g., the chromophores that absorb light do not substantially emit light by fluorescence or other radiative transition pathways. Certain embodiments of the chromophore assemblies described herein are designed such that one of the species of the assembly emits light, whereas the remainder of the species either absorb light or transfer energy, or both, to the emitting chromophore. The terminal chromophore may emit light to a PV cell optically coupled to the solar concentrator. In some examples, the terminal chromophore may be selected such that its light emission is red-shifted from the absorption spectrum of the other chromophores, or other species in the complex, to reduce the likelihood of re-absorption events that may lower the efficiency of the device. Where a first chromophore is used in combination with J-aggregates (or other types of aggregates), the first chromophore may be selected to absorb light, transfer energy to the J-aggregates, and the J-aggregates emit light at a wavelength that is red-shifted compared to the wavelength of the absorbed light. Similarly, J-aggregates may be selected to absorb light and transfer the energy to an emitting chromophore, which can be positioned adjacent to, or optically coupled to, a PV cell. Where a terminal chromophore is used in combination with an anti-Stokes material the terminal chromophore may receive energy from the anti-Stokes material and emit light that is blue-shifted compared to the wavelength of light absorbed by the anti-Stokes material.

In certain examples, the chromophores may be disposed on the substrate as shown in FIGS. 3A and 3B, whereas in other examples, the chromophores, chromophore assemblies and/or anti-Stokes materials may be in the substrate itself, e.g., embedded, impregnated, injected into, co-fabricated with or the like. For example, the chromophores may be dispersed within the substrate body or the substrate itself may be produced by disposing various thin films onto each other with the chromophores disposed in a thin film between two or more layers of the thin film substrate. The overall thin film stack may make up the entire solar concentrator device.

In accordance with certain examples, the solar concentrators disclosed herein may be configured such that light emission to the PV cell occurs by phosphorescence. As a chromophore absorbs optical radiation, an electron is promoted from the highest occupied molecular orbital (HOMO) to the lowest unoccupied molecular orbital (LUMO). The excited state may take several forms or spin states including singlet states and triplet states. For molecules with strong fluorescence, the singlet state has a strongly allowed radiative transition to the ground state. For molecules that emit light by phosphorescence, the radiative transition from triplet excited state to singlet ground state is spin forbidden and is also lower in energy than decay from a singlet state. Thus, the emission wavelength of phosphors is Stokes shifted (shifted to longer wavelengths) and also occurs for longer periods due to the spin forbidden nature of the transition. In particular, chromophore assemblies or J-aggregates can absorb radiation and transfer energy to a chromophore that emits light by phosphorescence. In some embodiments, the emitting chromophore in the chromophore complex may emit light by phosphorescence. In examples where an anti-Stokes material is used, the emitting chromophore may emit light by phosphorescence.

In accordance with certain examples, a chromophore that may be used as, with, or in addition to the chromophore assemblies and anti-Stokes materials may be an organometallic compound. In some examples, the organometallic compound may include a transition metal bonded, chelated or coordinated to one or more ligands. Such ligands may include groups having lone pair electrons that may be used to coordinate the metal center. The transition metal may be charged or uncharged and the overall complex may adopt many different geometries including, for example, linear, angular, trigonal planar, square planar, tetrahedral, octahedral, trigonal pyramidal, square pyramidyl, trigonal bipyramidal, rhombic and the like.

In certain examples, the compound disposed on or in the substrate may be a porphyrin compound. The porphyrin compound may be in a chromophore assembly or may be used in addition to a chromophore assembly. In some examples, the porphyrin compound has a general formula as shown in formula (I) below.

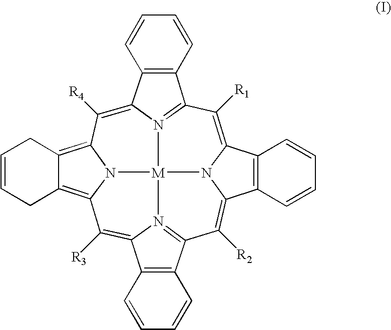

In some examples, each of R₁, R₂, R₃ and R₄ of formula (I) may independently be selected from a saturated or unsaturated hydrocarbon (e.g., a linear, branched or cyclic, substituted or unsubstituted hydrocarbon) having between one and ten carbon atoms, more particular having between one and six carbon atoms, e.g., between four and six carbon atoms. In certain examples, each of R₁, R₂, R₃ and R₄ may independently be selected from one or more of alkyl, alkenyl, alkynyl, aryl, aralkyl, naphthyl and other substituted or substituted hydrocarbons having one to ten carbon atoms. In some examples, at least one of R₁, R₂, R₃ and R₄ may include at least one non-carbon atom, e.g., may include at least one oxygen atom, one sulfur atom, one nitrogen atom or a halogen atom. In some examples at least one of R₁, R₂, R₃ and R₄ may be a heterocyclic group. In one embodiment, each of R₁, R₂, R₃ and R₄ is a substituted or unsubstituted aryl group. In some examples, each of R₁, R₂, R₃ and R₄ is benzyl (C₆H₅) as shown below in formula (II).

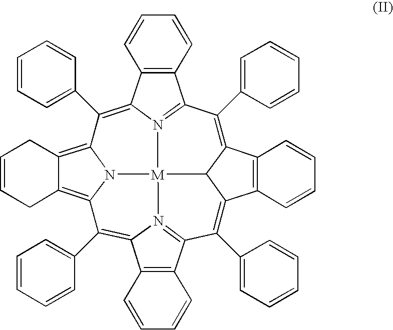

In formulae I and II, M may be any metal. In some examples, M may be a transition metal such that spin-orbital coupling is promoted to favor phosphorescence emission over fluorescence emission. In some examples, M may be a “heavy atom” having a atomic weight of at least about 100, more particularly at least about 190, e.g., an atomic weight of 200 or greater. In certain embodiments, M may be iridium, platinum, palladium, osmium, rhenium, hafnium, thorium, ruthenium and metals having similar electronic properties. Additional metals and groups for use in porphyrin compounds for use in a solar concentrator will be readily selected by the person of ordinary skill in the art, given the benefit of this disclosure. By selecting the concentration of porphyrin molecules in the chromophore or chromophore assembly, higher ordered structure can result, which can alter the optical properties of the chromophore, e.g., alter the absorption or emission wavelengths. In certain examples, different types of porphyrin molecules may be used in a chromophore assembly with certain molecules effective to absorb light and/or transfer energy and other molecules effective to emit light.

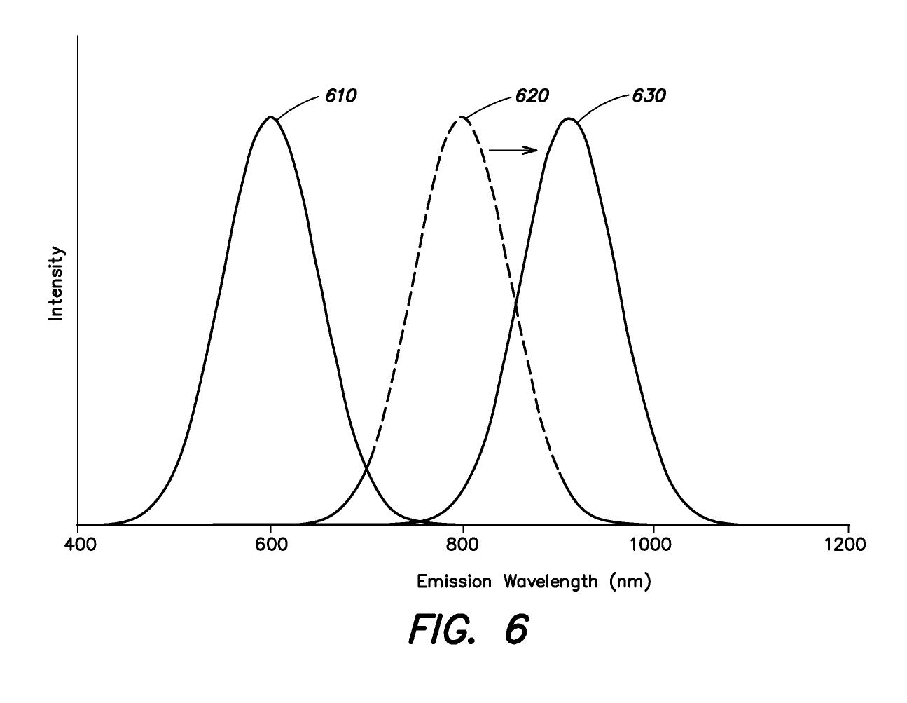

In accordance with certain examples, a composition comprising a material effective to absorb optical radiation within a first wavelength range and to emit the absorbed optical radiation by phosphorescence within a second wavelength range that is shifted, e.g., red-shifted or blue-shifted, from the first wavelength range is provided. In certain examples, the first and second wavelength ranges do not substantially overlap in wavelength. As used herein, “do not substantially overlap” refers to overlap by less than about 50 nm, more particularly less than about 20 nm, e.g., less than about 15 nm. In some examples, the composition may include one or more of a chromophore assembly, an anti-Stokes material or other chromophores. By selecting a composition that has reduced or substantially no overlap between the absorption wavelength spectrum and the emission wavelength spectrum, the overall efficiency of the LSC may be increased by, for example, reducing re-absorption. Selection and design of materials can result in shifting of the emission wavelength to higher or lower wavelengths and thus reduce or eliminate spectral overlap. An example of this feature is shown in FIG. 5. The absorption wavelength spectrum 510 is shown as being blue-shifted (anti-Stokes shift) from the phosphorescence emission wavelength spectrum 530. In contrast, there may be substantial overlap between the absorption wavelength spectrum and the fluorescence wavelength spectrum 520. By selecting suitable chromophores that decay primarily by phosphorescence emission, the spectral overlap between the absorption and light emission may be substantially reduced or eliminated.

In accordance with certain examples, the compositions for use in the LSC's disclosed herein may include one or more agents designed to red-shift the emission. Such red-shifting agents may be integral to the composition or may be added or doped into the composition in an effective amount to shift the light emission to longer wavelengths. Such red-shifting agents include, but are not limited to, heavy metals, chelators, compositions having one or more conjugated ring systems, matrix materials to trap the chromophore in and the like. In some examples, one or more steric groups may be added to limit or slow movement of the chromophore or to interact with, or affect, the pi-orbital systems of the chromophore.

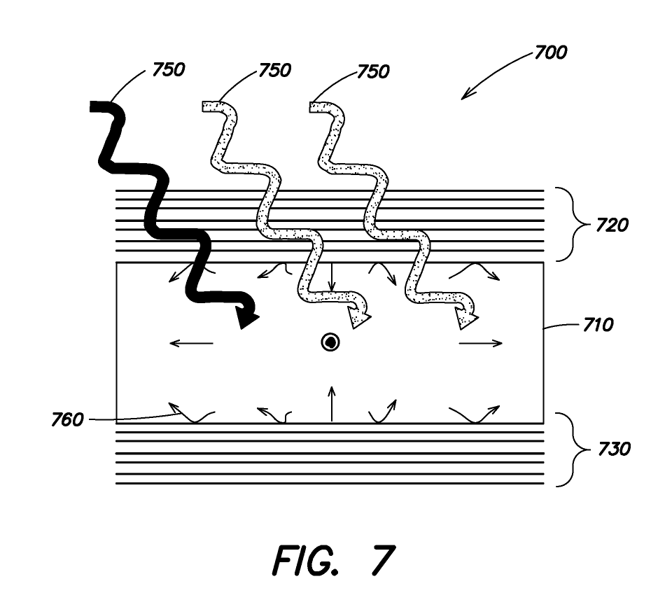

In accordance with certain examples, the solar concentrator may include a chromophore assembly, an anti-Stokes material, or both, in combination with a red-shifting agent. In some examples, the red-shifting agent may be effective to shift the wavelength of the chromophore, e.g., a metalloporphyrin compound, a dye, an aggregate, a chromophore assembly or the like, to a longer emission wavelength than that observed in the absence of the red-shifting agent. An illustration of this red-shifting is shown in FIG. 6. A light absorption spectrum 610 is shown as being blue-shifted in comparison to a light emission spectrum 620. By doping the waveguide with a red-shifting agent, or including or otherwise depositing or co-depositing a red-shifting agent with the chromophore, the light emission spectrum 620 may be red-shifted to a higher wavelength, as shown by light emission spectrum 630.

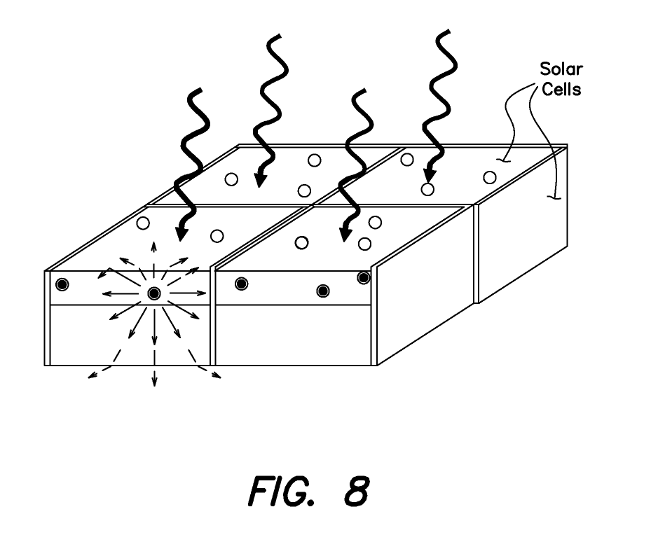

In accordance with certain examples, the devices disclosed herein may include one or more wavelength selective mirrors disposed thereon. In some examples, the wavelength selective minors may serve to increase the efficiency further by confining reflections within the substrate. For example, as emitted radiation is incident from inside the solar concentrator some of the incident light may be transmitted out of the substrate resulting in lower capturing of the light. By including at least one wavelength selective minor on a surface of the solar concentrator, the light may be retained internally and provided to one or more PV cells coupled to the solar concentrator. An illustration of this configuration for a solar concentrator is shown in FIG. 7. The device 700 comprises a substrate 710 comprising one or more chromophores disposed on or in the substrate 710, as described herein. The chromophores may be, for example, a chromophore assembly, an anti-Stokes material, a dye or other suitable materials. The device 710 also comprises a first reflective minor 720 on a first surface and a second reflective mirror 730 on an opposite surface. The first selective mirror 720 may be configured such that light of certain wavelengths, shown as arrows 750, is permitted to be passed by the first selective minor 720 into the substrate 710. The first selective mirror 720 may be designed such that reflected light, such as reflected light 760, is retained within the substrate, e.g., the reflected light is reflected back into the substrate by the first selective minor 720. Similarly, the second selective minor 730 may be designed such that it reflects incident light back into the substrate 710. The use of reflective minors permits trapping of the light within the substrate to increase the overall efficiency of the device 700.

In certain examples, the wavelength selective mirrors may comprise alternating thin films of, for example, one or more dielectric materials to provide a thin film stack than is operative as a wavelength selective mirror. In some examples, the thin films stacks may be produced by disposing thin film layers having different dielectric constants on a substrate surface. The exact number of thin films in the thin film stack may vary depending, for example, on the materials used, the desired transmission and reflection wavelengths and the like. In some examples, the thin film stack may include from about 6 thin film layers to about 48 thin film layers, more particularly about 12 thin film layers to about 24 thin film layers, e.g., about 16 thin film layers to about 12 thin film layers. The exact materials used to produce the thin film layers may also vary depending on the desired number of thin films layers, the desired transmission and reflection wavelengths and the like. In some examples, a first thin film may be produced using, for example, a material such as polystyrene, cryolite and the like. A second thin film may be disposed on the first thin film using, for example, metals such as tellerium, zinc selenide and the like. In some examples, each of the thin films may have a thickness that varies from about 20 nanometers to about 100 nanometers, more particularly, about 30 nanometers to about 80 nanometers, e.g., about 50 nanometers. One advantage of using thin films is that minors comprised of thin films may permit retention of light at all angles of incidence and polarizations to further increase the light trapping efficiency of the solar concentrator. Solar concentrators having such thin film mirrors can receive more light thus increasing the efficiency of the solar cell device.

In accordance with certain examples, to further decrease re-absorption of the light, it may be desirable to alter the local environment of the chromophores. The local environment can affect the electronic properties of the chromophores such that chromophores having the same composition, but in different local environments, may have different optical properties, e.g., different emission wavelengths. In certain examples, the environment of the chromophore may be altered or tuned such that the ground state or neutral chromophore (not excited by light) behaves differently than the excited molecule. For example, the environment of the chromophore may include, or be doped with, another molecule that is charged or has a high degree of charge separation, e.g., a high dipole moment. As the excited state of many chromophores exhibits a large dipole moment, if the excited chromophore has spatial or rotational degrees of freedom, it can move or rotate to decrease the energy of the system which generally results in red-shifting of the emission wavelength. As discussed elsewhere herein, red-shifting of the emission spectrum can result in a decrease in the absorption and emission spectra, which decreases the likelihood of re-absorption and increases the overall efficiency of the solar concentrator. For example, the environment surrounding a chromophore assembly or an anti-Stokes material may be altered by doping with a charged species or a molecule with a high degree of charge separation to alter the optical properties of the chromophore assembly or the anti-Stokes material.

In certain examples, the local environment of the chromophore may be altered by adding or doping a molecule into the substrate and/or co-depositing the molecule with the chromophore. Such doping or co-depositing can result in solid state solvation of the chromophore and alter the electronic properties of the excited state to alter the emission wavelength. In some examples, an effective amount of the dopant may be added to the molecule such that the emission wavelength is red-shifted by about 5 nm to about 50 nm, more particularly about 10 nm to about 40 nm, e.g., about 20 nm to about 30 nm. The exact nature of the composition used as a dopant may vary and, in particular, molecules having a dipole moment of at least 2 debyes, more particularly at least 3 debyes, e.g., about 5 debyes or more may be used. In some examples, the dopant may provide a polar matrix that alters the optical properties of the chromophore.

In certain examples, the concentration of the dopant may be from about 0.5% to about 99%, more particular about 1% to about 90%, based on the weight of the host material. For example, if 10% by weight of dopant is used, then when the entire mass of the film is considered, 10% of its mass is from the dopant. The dopant may be any material, other than the emitting chromophore, that may alter the local environment of the emitting chromophore. For example, the host material itself may be considered a dopant if it alters the local environment of the emitting chromophore. In some examples, the dopant may be one or more materials including, but not limited to, tris(8-hydroxyquinoline), laser dyes such as, for example, 2-methyl-6-[2-(2,3,6,7-tetrahydro-1H,5H-benzo[i,j]quinolizin-9-yl)-ethenyl]-4H-pyran-4-ylidene]propane dinitrile (DCM2), camphoric anhydride, Indandione-1,3 pyridinium betaine compounds, and azobenzene chromophores. Additional dopants and concentrations to alter the local environment of a chromophore will be readily selected by the person of ordinary skill in the art, given the benefit of this disclosure.

In some examples, the dopant itself may be present in an amount that permits transfer of energy, and optionally emission of light by the dopant, but not at so high a concentration or amount that substantial direct light absorption by the dopant itself occurs. For example, it may be desirable to select suitable concentrations of the materials such that light absorption by one of the species dominates. In some examples where a dopant is present, the dopant may be present at an amount such that direct light absorption by the dopant is 15% or less, e.g., 10% or less or 0-5%, of the total photons incident on the device. It will be within the ability of the person of ordinary skill in the art, given the benefit of this disclosure, to select suitable amounts of the materials in the LSC's disclosed herein such that one or more desired species preferentially absorbs light and one or more desired species preferentially emits light.

In accordance with certain examples, the efficiency of photon trapping by the solar concentrator may depend, at least in part, on the angle or orientation of the emitting chromophore. Chromophores oriented to absorb maximally may have a low trapping efficiency, whereas chromophores oriented to trap efficiently may absorb weakly. By controlling the orientation of the chromophores, both light trapping efficiency and light absorption may be increased. In particular, the orientation of the terminal chromophore, e.g., the light emitting chromophore, may be selected such that light trapping efficiency is maximized. In embodiments where energy transfer is used to deliver energy to the terminal chromophore, the weak light absorption by the terminal chromophore is not relevant. The absorbing chromophores may be either randomly oriented or oriented to jointly optimize light absorption and energy transfer efficiency to the terminal chromophore. It will be within the ability of the person of ordinary skill in the art to design solar concentrators that include selectively oriented chromophores. In some examples, a first chromophore may be oriented at an angle to increase absorption of light incident on the substrate. This result may occur, for example, if the transition dipole of the first chromophore was oriented perpendicular to the incident light rays and/or parallel to the guiding direction. For example, by orienting the first chromophore at a selected angle the amount of light absorbed may be increased by 10% to about 50% or more as compared to a random orientation. In other examples, the second chromophore may be oriented at an angle to increase the light-trapping efficiency. This result may occur, for example, if the transition dipole of the second chromophore was oriented parallel to the incident light rays and/or perpendicular to the guiding direction. For example, by orienting the second chromophore at a selected angle the light-trapping efficiency may be increased by 10% to about 50% or more compared to a random orientation. In certain embodiments, the chromophore assembly may include oriented chromophores such that the overall assembly includes an absorbing chromophore oriented at an angle to increase absorption of light and an emitting chromophore oriented at an angle to increase the light-trapping efficiency. J-aggregates and combination of materials may also provide a similar result. For example, a first set of aggregates may be oriented in one direction, and another set of aggregates, e.g., having the same or different composition as the first set of aggregates, may be oriented in a different direction.

In certain examples, the solar concentrator of the devices disclosed herein may include a substrate comprising at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore. At least one of the first and second chromophores may be selected from chromophore assemblies, anti-Stokes materials or combinations thereof. In some examples, the solar concentrator may include one or more wavelength selective minors on a surface. In other examples, the chromophore(s) may be disposed in a polar matrix. The solar concentrator may be optically coupled to the PV cell to provide light to the PV cell.

In other embodiments, the solar concentrator of the devices disclosed herein may include a substrate comprising at least first and second closely spaced chromophores disposed on or in the substrate in a manner to receive optical radiation, the first chromophore effective to absorb at least some optical radiation and to transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least five times greater than the concentration of the second chromophore. At least one of the first and second chromophores may be selected from chromophore assemblies, anti-Stokes materials or combinations thereof. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In additional embodiments, the solar concentrator of the devices disclosed herein may include a substrate comprising a plurality of chromophores disposed on or in the substrate in a manner to receive optical radiation, the plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. At least one of the plurality of chromophores may be selected from chromophore assemblies, anti-Stokes materials or combinations thereof. In certain examples, all of the plurality of chromophores may be located within a chromophore assembly. In some examples, the solar concentrator may include one or more wavelength selective minors on a surface. In other examples, one or more of the chromophores may be disposed in a polar matrix. The solar concentrator may be optically coupled to the PV cell to provide light to the PV cell.

In some examples, the solar concentrator of the devices disclosed herein may include a substrate comprising a film disposed on the substrate in a manner to receive at least some optical radiation, the film comprising at least a first chromophore and a second chromophore, the first chromophore effective to absorb at least one wavelength of at least some of the optical radiation and further effective to transfer at least some of the energy by Förster energy transfer to the second chromophore, the second chromophore effective to emit at least some of the transferred energy at a wavelength that is red-shifted from the wavelength absorbed by the first chromophore. At least one of the first and second chromophores may be selected from chromophore assemblies, anti-Stokes materials or combinations thereof. In some examples, the solar concentrator may include one or more wavelength selective mirrors on a surface. In other examples, the first chromophore, the second chromophore or both may be disposed in a polar matrix. The solar concentrator may be optically coupled to the PV cell to provide light to the PV cell.

In certain embodiments, the solar concentrator of the devices disclosed herein may include a substrate comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. At least one of the plurality of chromophores may be selected from chromophore assemblies, anti-Stokes materials or combinations thereof. In some examples, the solar concentrator may include one or more wavelength selective mirrors on a surface. In other examples, the one or more of the chromophores may be disposed in a polar matrix. The solar concentrator may be optically coupled to the PV cell to provide light to the PV cell.

In some embodiments, the solar concentrator of the devices disclosed herein may include a substrate comprising a film disposed on the substrate in a manner to receive at least some optical radiation, the film comprising at least a first chromophore and a second chromophore, the first chromophore effective to absorb at least some optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in the film at a concentration at least five times greater than the concentration of the second chromophore in the film. At least one of the first and second chromophores may be selected from chromophore assemblies, anti-Stokes materials or combinations thereof. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In certain examples, the solar concentrator of the devices disclosed herein may include a substrate comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain embodiments, the concentrator may include at least one of a chromophore assembly, anti-Stokes material and combinations thereof. In some examples, the solar concentrator may include one or more wavelength selective mirrors on a surface. In other examples, the at least one component of the material may be disposed in a polar matrix. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to higher wavelengths such that the first and second wavelength ranges do not substantially overlap in wavelength. At least one of the first and second chromophores may be a chromophore assembly. In some examples, the solar concentrator may include one or more wavelength selective minors on a surface. In other examples, the material may be disposed in a polar matrix. The solar concentrator may be optically coupled to the PV cell to provide light to the PV cell.

In other examples, the solar concentrator of the devices disclosed herein may include a substrate comprising a composition disposed on or in the substrate in a manner to absorb at least some optical radiation, the composition comprising at least one chromophore assembly comprising, for example, a porphyrin, a chlorin, an aggregate, a cyanine dye, a perylene bisimide dye and/or a phycobilisome. In some examples, the chromophore assembly may be used in combination with one or more other chromophores or chromophore assemblies. In some examples, the solar concentrator may include one or more wavelength selective minors on a surface. In other examples, at least one of the chromophores may be disposed in a polar matrix. The solar concentrator may be optically coupled to the PV cell to provide light to the PV cell.

In additional embodiments, the solar concentrator of the devices disclosed herein may include a substrate comprising a composition disposed on or in the substrate in a manner to absorb at least some optical radiation, the composition comprising at least one chromophore assembly comprising, for example, a porphyrin, a chlorin, an aggregate, a cyanine dye, a perylene bisimide dye and/or a phycobilisome effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain examples, the chromophore assembly may be used in combination with one or more other chromophores or chromophore assemblies. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In certain embodiments, the solar concentrator of the devices disclosed herein may include a substrate comprising a composition disposed on or in the substrate in a manner to absorb at least some optical radiation, the composition comprising at least one chromophore assembly comprising, for example, a porphyrin, a chlorin, an aggregate, a cyanine dye, a perylene bisimide dye and/or a phycobilisome effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising at least one a chromophore assembly comprising, for example, a porphyrin, a chlorin, an aggregate, a cyanine dye, a perylene bisimide dye and/or a phycobilisome effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the chromophore assembly to shift the second wavelength range to a higher wavelength range such that the first and second wavelength ranges do not substantially overlap in wavelength. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In certain examples, the solar concentrator of the devices disclosed herein may include a substrate comprising a composition disposed on or in the substrate in a manner to absorb at least some optical radiation, the composition comprising at least one organometallic compound in combination with, or part of, one or more of a chromophore assembly, an anti-Stokes material or other suitable chromophores. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In some examples, the solar concentrator of the devices disclosed herein may include a substrate comprising a composition disposed on or in the substrate in a manner to absorb at least some optical radiation, the composition comprising at least one organometallic compound in combination with, or part of, one or more of a chromophore assembly, an anti-Stokes material or other suitable chromophores. The composition may be effective to absorb the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, at least one of the organometallic compound and other chromophores may be disposed in a polar matrix. The solar concentrator may be optically coupled to the PV cell to provide light to the PV cell.

In certain embodiments, the solar concentrator of the devices disclosed herein may include a substrate comprising a composition disposed on or in the substrate in a manner to absorb at least some optical radiation, the composition comprising at least one organometallic compound in combination with, or part of, one or more of a chromophore assembly, an anti-Stokes material or other suitable chromophores. The composition may be effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In some examples, the solar concentrator may include one or more wavelength selective mirrors on a surface. In other examples, at least one of the organometallic compound and other chromophores may be disposed in a polar matrix. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising at least one organometallic compound in combination with, or part of, one or more of a chromophore assembly, an anti-Stokes material or other suitable chromophores. The composition may be effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the organometallic compound to shift the second wavelength range to a higher wavelength range such that the first and second wavelength ranges do not substantially overlap in wavelength. In some examples, the solar concentrator may include one or more wavelength selective mirrors on a surface. In other examples, at least one of the organometallic compound and the other chromophores may be disposed in a polar matrix. The solar concentrator may be optically coupled to the PV cell to provide light to the PV cell.

In certain examples, the solar concentrator of the devices disclosed herein may include a substrate having a refractive index of greater than or equal to 1.7 and comprising a chromophore disposed on or in the substrate and effective to absorb optical radiation. The chromophore may be, or may include, a chromophore assembly, an anti-Stokes material or include both. In some examples, the solar concentrator may include one or more wavelength selective minors on a surface. In other examples, at least one chromophore of the concentrator may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising at least first and second closely spaced chromophores disposed on or in the substrate in a manner to receive at least some optical radiation, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In certain embodiments, at least one of the first and second chromophores may be a chromophore assembly or an anti-Stokes material or include both. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In certain embodiments, the solar concentrator of the devices disclosed herein may include a substrate having a refractive index of greater than or equal to 1.7 and comprising a plurality of chromophores disposed on or in the substrate in a manner to receive at least some optical radiation, the plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In certain examples, at least one of the plurality of chromophores may be a chromophore assembly or an anti-Stokes material or include both. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising at least first and second closely spaced chromophores disposed on or in the substrate in a manner to receive at least some optical radiation, the first chromophore effective to absorb at least some optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least five or ten times greater than the concentration of the second chromophore. In certain examples, at least one of the chromophores may be a chromophore assembly or an anti-Stokes material or include both. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In certain embodiments, the solar concentrator of the devices disclosed herein may include a substrate having a refractive index of at least about 1.7 and comprising a film disposed on the substrate in a manner to receive optical radiation, the film comprising at least a first chromophore and a second chromophore, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In certain embodiments, at least one of the chromophores may be a chromophore assembly or an anti-Stokes material or include both. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In certain examples, the solar concentrator of the devices disclosed herein may include a substrate having a refractive index of greater than or equal to 1.7 and comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore effective to emit at least some of the received energy at a wavelength that is red-shifted from the at least one wavelength absorbed by the plurality of chromophores. In certain examples, at least one of the chromophores may be a chromophore assembly or an anti-Stokes material or include both. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising a film disposed on the substrate in a manner to receive at least some optical radiation, the film comprising at least a first chromophore and a second chromophore, the first chromophore effective to absorb at least some optical radiation and transfer at least some of the energy to the second chromophore, the second chromophore effective to emit at least some of the transferred energy at a wavelength that is red-shifted from a wavelength of optical radiation absorbed by the first chromophore, in which the first chromophore is present in the film in a concentration at least five or ten times greater than the concentration of the second chromophore in the film. In certain examples, at least one of the chromophores may be a chromophore assembly or an anti-Stokes material or include both. In some examples, the solar concentrator may include one or more wavelength selective mirrors on a surface. In other examples, at least one of the chromophores may be disposed in a polar matrix. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain examples, the material may include a chromophore assembly or an anti-Stokes material or include both. In some examples, the solar concentrator may include one or more wavelength selective mirrors on a surface. In other examples, at least one of the materials may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In certain examples, the material may include a chromophore assembly or an anti-Stokes material or include both. In some examples, the material may include one or more wavelength selective mirrors on a surface. In other examples, at least one component of the material may be disposed in a polar matrix. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound in combination with, or part of, a chromophore assembly or an anti-Stokes material or include both. In some examples, the solar concentrator may include one or more wavelength selective minors on a surface. In other examples, at least one of the chromophores may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and a composition disposed on or in the substrate in a manner to absorb at least some optical radiation, the composition comprising at least one porphyrin compound in combination with, or part of, a chromophore assembly or an anti-Stokes material. The composition may be effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective minors on a surface. In other examples, at least one of the chromophores may be disposed in a polar matrix. The solar concentrator may be optically coupled to the PV cell to provide light to the PV cell.

In additional examples, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound in combination with, or part of, a chromophore assembly or an anti-Stokes material or include both. The composition may be effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In some examples, the solar concentrator may include one or more wavelength selective minors on a surface. In other examples, at least one of the materials in the composition may be disposed in a polar matrix. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound in combination with, or part of, a chromophore assembly or an anti-Stokes material or include both. The composition may be effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the porphyrin compound to shift the second wavelength range to a higher wavelength range such that the first and second wavelength ranges do not substantially overlap in wavelength. In some examples, the solar concentrator may include one or more wavelength selective mirrors on a surface. In other examples, at least one of the materials of the composition may be disposed in a polar matrix. The solar concentrator may be optically coupled to the PV cell to provide light to the PV cell.

In some examples, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound in combination with, or part of, a chromophore assembly or an anti-Stokes material or include both. In some examples, the solar concentrator may include one or more wavelength selective mirrors on a surface. In other examples, at least one of the organometallic compound, the chromophore assembly and the anti-Stokes material may be disposed in a polar matrix. The solar concentrator may be optically coupled to the PV cell to provide light to the PV cell.

In certain examples, the solar concentrator of the devices disclosed herein may include a substrate having a refractive index of greater than or equal to 1.7 and a composition disposed on or in the substrate in a manner to absorb at least some optical radiation, the composition comprising at least one organometallic compound in combination with, or part of, a chromophore assembly, an anti-Stokes material or include both. In certain examples, the composition may be effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective minors on a surface. In other examples, at least one component of the composition may be disposed in a polar matrix. The solar concentrator may be optically coupled to the PV cell to provide light to the PV cell.

In some embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound in combination with, or part of, a chromophore assembly, an anti-Stokes material or include both. The composition may be effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In some examples, the solar concentrator may include one or more wavelength selective minors on a surface. In other examples, at least one component of the composition may be disposed in a polar matrix. The solar concentrator may be optically coupled to the PV cell to provide light to the PV cell.

In certain examples, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound in combination with, or part of, a chromophore assembly, an anti-Stokes material or include both. In some examples, the composition may be effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the organometallic compound to shift the second wavelength range to a higher wavelength range such that the first and second wavelength ranges do not substantially overlap in wavelength. In some examples, the solar concentrator may include one or more wavelength selective minors on a surface. In other examples, at least one component of the composition may be disposed in a polar matrix. The solar concentrator may be optically coupled to the PV cell to provide light to the PV cell.

In some embodiments, the solar concentrator of the devices disclosed herein may include a substrate configured to trap at least 80% of the quanta of radiation incident on the substrate and a chromophore disposed on or in the substrate and effective to absorb at least some optical radiation and emit at least some of the absorbed optical radiation at a longer wavelength. In certain examples, the chromophore may be a chromophore assembly, an anti-Stokes material and/or other suitable chromophores described herein. In some examples, the solar concentrator may include one or more wavelength selective mirrors on a surface. In other examples, the chromophore may be disposed in a polar matrix. The solar concentrator may be optically coupled to the PV cell to provide light to the PV cell.

In certain embodiments, the solar concentrator of the devices disclosed herein may include a substrate configured to trap at least 80% of the quanta of radiation incident on the substrate and comprising at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore. In certain examples, at least one of the first and second chromophores may be a chromophore assembly, an anti-Stokes material or include both. In some examples, the solar concentrator may include one or more wavelength selective minors on a surface. In other examples, at least one of the chromophores may be disposed in a polar matrix. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising at least first and second closely spaced chromophores disposed on or in the substrate in a manner to receive at least some optical radiation, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in a concentration at least five or ten times greater than the concentration of the second chromophore. In certain examples, at least one of the first and second chromophores may be a chromophore assembly, an anti-Stokes material or include both. In some examples, the solar concentrator may include one or more wavelength selective minors on a surface. In other examples, at least one of the chromophores may be disposed in a polar matrix. The solar concentrator may be optically coupled to a PV cell to provide light to the PV cell.

In certain embodiments, the solar concentrator of the devices disclosed herein may include a substrate configured to trap at least 80% of the quanta of radiation incident on the substrate and comprising at least first and second closely spaced chromophores disposed on the substrate in a manner to receive at least some optical radiation, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least five or ten times greater than the concentration of the second chromophore. In certain examples, at least one of the first and second chromophores may be a chromophore assembly, an anti-Stokes material or include both. In some examples, the solar concentrator may include one or more wavelength selective minors on a surface. In other examples, at least one of the chromophores may be disposed in a polar matrix. The solar concentrator may be optically coupled to a PV cell to provide light to the PV cell.

In certain examples, the solar concentrator of the devices disclosed herein may include a substrate configured to trap at least 80% of the quanta of radiation incident on the substrate and comprising a film disposed on the substrate in a manner to receive at least some optical radiation, the film comprising at least a first chromophore and a second chromophore, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In certain embodiments, at least one of the first and second chromophores may be a chromophore assembly, an anti-Stokes material or include both. In some examples, the solar concentrator may include one or more wavelength selective mirrors on a surface. In other examples, at least one of the chromophores may be disposed in a polar matrix. The solar concentrator may be optically coupled to a PV cell to provide light to the PV cell.

In other examples, the solar concentrator of the devices disclosed herein may include a substrate configured to trap at least 80% of the quanta of radiation incident on the substrate and comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In certain examples, at least one of the plurality of chromophores or the terminal chromophore may be or include a chromophore assembly, an anti-Stokes material or both. In some examples, the solar concentrator may include one or more wavelength selective minors on a surface. In other examples, at least one of the chromophores may be disposed in a polar matrix. The solar concentrator may be optically coupled to a PV cell to provide light to the PV cell.

In certain embodiments, the solar concentrator of the devices disclosed herein may include a substrate configured to trap at least 80% of the quanta of radiation incident on the substrate and comprising a film disposed on the substrate in a manner to receive at least some optical radiation, the film comprising at least a first chromophore and a second chromophore, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in the film in a concentration at least five or ten times greater than the concentration of the second chromophore in the film. In certain examples, at least one of the first and second chromophores may be a chromophore assembly, an anti-Stokes material or include both. In some examples, the solar concentrator may include one or more wavelength selective minors on a surface. In other examples, at least one of the chromophores may be disposed in a polar matrix. The solar concentrator may be optically coupled to a PV cell to provide light to the PV cell.

In some embodiments, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain examples, the material may include a chromophore assembly, an anti-Stokes material or include both. In some examples, the solar concentrator may include one or more wavelength selective mirrors on a surface. In other examples, at least one component in the material may be disposed in a polar matrix. The solar concentrator may be optically coupled to a PV cell to provide light to the PV cell.

In additional examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to higher wavelengths such that the first and second wavelength ranges do not substantially overlap in wavelength. In certain examples, the material may include a chromophore assembly, an anti-Stokes material or include both. In some examples, the solar concentrator may include one or more wavelength selective mirrors on a surface. In other examples, at least one component in the material may be disposed in a polar matrix. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising a chromophore assembly, an anti-Stokes material or both. In some examples, the solar concentrator may include one or more wavelength selective mirrors on a surface. In other examples, at least one of the chromophores may be disposed in a polar matrix. The solar concentrator may be optically coupled to a PV cell to provide light to the PV cell.

In certain examples, the solar concentrator of the devices disclosed herein may include a substrate configured to trap at least 80% of the quanta of radiation incident on the substrate and a composition disposed on or in the substrate in a manner to absorb at least some optical radiation, the composition comprising at least one chromophore in combination with a chromophore assembly and an anti-Stokes material. In some examples, the composition may be effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the solar concentrator may include one or more wavelength selective mirrors on a surface. In other examples, at least one component of the composition may be disposed in a polar matrix. The solar concentrator may be optically coupled to a PV cell to provide light to the PV cell.

In certain embodiments, the solar concentrator of the devices disclosed herein may include a substrate configured to trap at least 80% of the quanta of radiation emitted in the substrate and comprising a composition disposed on or in the substrate in a manner to absorb at least some optical radiation, the composition comprising at least one chromophore in combination with a chromophore assembly. The composition may be effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In some examples, the solar concentrator may include one or more wavelength selective mirrors on a surface. In other examples, at least one component of the composition may be disposed in a polar matrix. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one chromophore in combination with an anti-Stokes material. The composition may be effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the porphyrin compound to shift the second wavelength range to a higher wavelength range such that the first and second wavelength ranges do not substantially overlap in wavelength. In some examples, the solar concentrator may include one or more wavelength selective minors on a surface. In other examples, at least one component of the composition may be disposed in a polar matrix. The solar concentrator may be optically coupled to a PV cell to provide light to the PV cell.

In other examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one chromophore assembly in combination with an anti-Stokes material. In some examples, the solar concentrator may include one or more wavelength selective mirrors on a surface. In other examples, at least one component of the composition may be disposed in a polar matrix. The solar concentrator may be optically coupled to a PV cell to provide light to the PV cell.

In accordance with certain examples, the solar concentrators disclosed herein may be used with many different types of PV cells and PV cells having different efficiencies. By using the solar concentrators disclosed herein, the efficiency of each PV cell need not be the same. For example, it may be desirable to use a high efficiency PV cell without a concentrator and use a low efficiency PV cell with a concentrator to provide substantially the same efficiency for each of the PV cells. In addition, it may be desirable to selectively position the PV cells in an array to utilize the different efficiencies. Electrical power losses from heating increase with increasing current flowing in a module circuit. The current is minimized with a serial configuration. For this reason, the typical configuration of individual solar cells when connected in a module is in series. For cells connected in this way, it is desirable that each cell passes the same amount of current. Otherwise, PV cells with lower currents will limit the total current that can flow through the whole module limiting the power conversion efficiency. In a typical module, effort and cost is devoted to testing and sorting individual cells such that all cells to be put into a module are as close to identical in performance as possible. Also, they are typically all the same size. The light intensity reaching the edges of a luminescent solar concentrator (LSC) depends on position on the guide. Since the light intensity depends on position, the current passing through each solar cell should also depend on position. If identical PV cells are used (either in size or performance), the module power conversion efficiency will be limited by the cell receiving the least light and thus passing the least current.

In accordance with certain examples, the geometry of the PV cell may also be tailored or designed such that PV cells having different efficiencies may be used with one or more of the solar concentrators disclosed herein. For example, the amount of light reaching each of the collection edges depends, ay least in part, on waveguide geometry. For manufacturing simplicity and cost, many solar concentrators may be produced in rectangular or square configurations, but other geometries are possible. For a simple rectangular case, the light reaching the corners will be lower than those edges closest to the center as optical losses increase with the distance light travels in the waveguide. By adjusting the PV cell efficiency as a function of position, higher efficiency cells can be used in the edges near the corners and lower efficiency cells can be used in the edges near the solar concentrator center. Using this arrangement, the current flowing through each PV cell may be substantially equal and module efficiency is not limited by lower current PV cells. This arrangement permits for the use of cells of variable performance efficiencies instead of using the lower efficiency cells in less valuable lower efficiency modules.

In certain examples, the dimension of the PV cells may also be adjusted to provide similar efficiencies. For example, by adjusting the cell dimensions of identically efficient cells, similar current matching is possible. If all cell heights are identical (set, for example, by the edge thickness), then the cell lengths may be altered to accommodate the differing light intensities as a function of position. PV cells at the edges closest to the corners may be longer, and cells at the edges closest to the concentrator center may be shorter. The use of such variable size PV cells with the concentrators disclosed herein provides similar efficiencies to increase the overall efficiency of a solar cell array.

In accordance with certain examples, the various materials used in the concentrators disclosed herein, e.g., chromophores, chromophore assemblies, anti-Stokes materials, red-shifting agents, thin films, etc., may be disposed using numerous different methods including, but not limited to, painting, brushing, spin coating, casting, molding, sputtering, vapor deposition (e.g., physical vapor deposition, chemical vapor deposition and the like), plasma enhanced vapor deposition, pulsed laser deposition and the like. In some examples, organic vapor phase deposition (OVPD) may be used to deposit at least one of the components of the solar concentrators disclosed herein. OVPD may be used, for example, to dispose or coat a waveguide with one or more chromophores, red-shifting agents, heavy metals or the like. In some examples, OVPD may be used to produce a solar concentrator by disposing a vapor phase of the chromophore on a substrate and optionally curing or heating the substrate. Illustrative devices for OVPD are commercially available, for example, from Aixtron (Germany). Suitable methods, parameters and devices for OVPD are described, for example in Baldo et al., Appl. Phys. Lett. 71(2), 3033-3035, 1997.

In accordance with certain examples, a high index epoxy or adhesive may be used to attach the solar concentrators disclosed herein to a PV cell. For example, solar cells may be produced using a high index adhesive or epoxy such that index mismatching may be avoided or substantially reduced. In one illustration, to reduce the light coupling losses, it may be desirable to reduce optical reflections as light passes from the LSC into the PV cell. There may be an index mismatch between the waveguide and the solar cell, but this mismatch need not introduce large reflections if the solar cell is covered by an antireflection coating (most solar cells have them built into their structure). These antireflection coatings may be designed for light that is incident from air but can be redesigned for light that is incident from a solar concentrator. If the PV cells are attached to the LSC by an epoxy or an adhesive, the epoxy or adhesive may introduce unwanted reflections, and the thickness of the epoxy or adhesive may be difficult to control. By using epoxies which are index-matched to the waveguide, the antireflection coating of the solar cell may be designed for light incident from the waveguide and the exact thickness of the epoxy or adhesive is less important. Thus, by using an epoxy or adhesive whose index is matched to the substrate or waveguide, the overall efficiency of a solar cell may be increased.

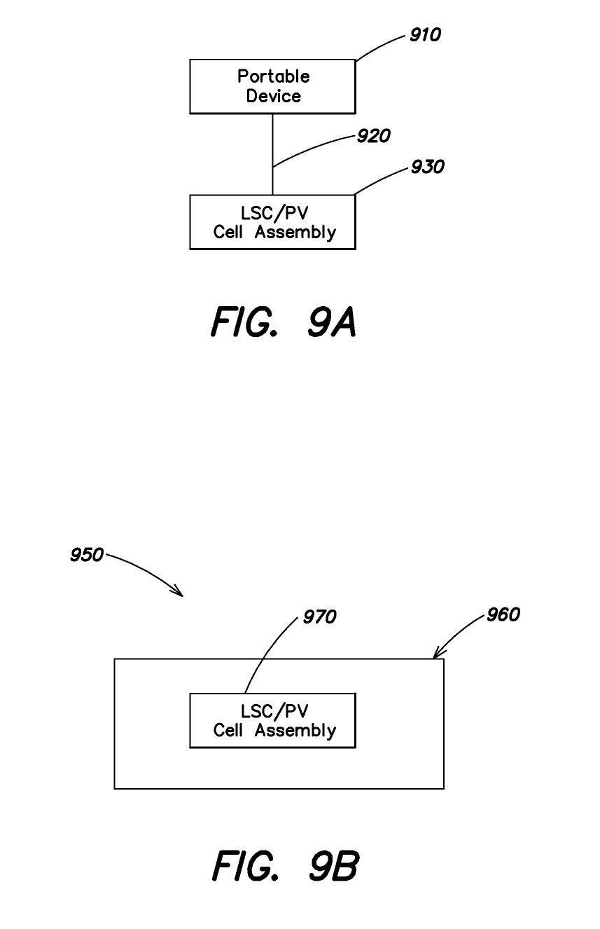

In accordance with certain examples, the PV cells may be embedded or otherwise integrated into the solar concentrators disclosed herein. For example, where the substrate is producing using one or more polymers, e.g., a plastic, it may be desirable to embed the PV cell into the waveguide rather than attach the PV cell at an edge of the waveguide. A configuration of such embedded PV cell is shown in FIG. 8. In embodiments where the concentrator is produced using a plastic, the PV cell can be embedded in the plastic melt when the liquid material is cast or injection molded. This process permits omission of any epoxy or adhesive joints to attach a PV cell to the solar concentrator. As the joints are been removed, the index matching to a substrate is not required, and the antireflection coating on the PV cell may be designed directly for light incident from the waveguide. In addition, in a solar concentrator that is limited in geometric optical gain by re-absorption losses, very large modules can be made with lower optical gains. For example, a chromophore may limit the concentration factor to 100, e.g., corresponding to waveguide dimensions of 80 cm×80 cm×2 mm. If a module with larger dimension is desired, e.g., 160 cm×160 cm×2 mm, four concentrators would be tiled in an array inside the module. This design constraint may be avoided by embedding the PV cells in a grid within the solar concentrator, so the module can be made larger without sacrificing performance due to chromophore re-absorption.

In accordance with certain examples, the solar cell devices disclosed herein may be arranged with other solar cell devices disclosed herein to provide an array of solar cells. For example, the system may comprise a plurality of photovoltaic cells constructed and arranged to receive optical radiation from the sun, wherein at least one of the plurality of photovoltaic cells is coupled to a solar concentrator as described herein. In particular, the solar concentrator of the system may be any one or more of the solar concentrator disclosed herein. In addition, the system may include a plurality of solar concentrators with each of the solar concentrators being the same type of solar concentrator. In other examples, many different types of solar concentrators may be present in the system.

In accordance with certain examples, methods of increasing the efficiency of a PV cell are disclosed. In certain examples, the method comprises providing concentrated optical radiation to a photovoltaic cell from a solar concentrator, the solar concentrator comprising any of the solar concentrators disclosed herein. In other examples, the method may further include embedding the PV cells in the solar concentrators to further increase the efficiency of the PV cells. Other methods of using the solar concentrators disclosed herein to increase the efficiency of PV cells and systems including PV cells will be readily selected by the person of ordinary skill in the art, given the benefit of this disclosure.

In accordance with certain examples, two or more waveguides may be optically coupled such that one of the waveguides absorbs light within a first wavelength range and at least one of the other waveguides absorbs light within a second wavelength range different from the first wavelength range. Devices that include two or more waveguides are referred to in certain instances herein as tandem devices. The tandem device may include two solar concentrators as described herein or may include a solar concentrator coupled to an existing thin film photovoltaic cell. Converting light to electrical current with multiple electrical bandgaps in a tandem configuration allows a higher fraction of the lights optical power to be converted to electrical power. In a tandem device comprised of a top system comprised of a concentrator collecting light to be converted at a high bandgap solar cell and a bottom system comprised of a lower electrical bandgap thin film photovoltaic, the requirements of current matching are alleviated as the two systems no longer need to be connected serially. In a serial configuration, the currents desirably match or the cell with the lowest current can limit the overall current and thus overall efficiency of the device.

In the configuration where the top solar cell is replaced by a top LSC, current matching is not necessary as electrodes are not shared. The LSC may be attached or otherwise coupled to one or more solar cells with a selected bandgap so a greater fraction of each photon's power will be extracted. Finally, the light that escapes the LSC from the bottom may still be captured and converted by the lower solar cell, so the losses in the LSC will be partially diminished. The combination of an LSC with a thin film solar cell provides numerous advantages including, but not limited to, a cheaper method to improve the module efficiency compared to just the underlying solar cell alone.

In certain examples, numerous different types of solar cells may be used with an LSC to provide a tandem device, and the exact type and nature of the solar cell is not critical. Illustrative solar cells for use with a LSC in a tandem device include, but are not limited to, chalcopyrite based (CuInSe₂, CuInS₂, CuGaSe₂), cadmium telluride (CdTe) amorphous, nanocrystalline, polycrystalline, or multicrystalline silicon, and amorphous silicon-germanium (SiGe) or germanium (Ge). The LSC may be used with any one or more of the LSC's described herein. In some examples, the LSC may be used with two or more thin film PV cells, whereas in some examples two or more LSC's may be used with a single thin film PV cell. Other combinations of LSC's and thin film PV cells to provide a tandem device will be readily selected by the person of ordinary skill in the art, given the benefit of this disclosure.

In certain examples, the solar concentrators described herein may be used in or with a portable device. Portable devices are those devices that may be placed or moved by a user with ease and typically function using direct current from a battery or fuel cell source. For example, widely distributed sensors, mobile electronics, and communication and entertainment appliances are used in applications that require wireless operability. Battery power is often a convenient method for provided portability and wireless use. However, electrochemical storage devices require periodic replacement or recharging, which can be expensive and time consuming. Micropower generation, or the transduction of ambient energy sources from the local environment, offers an attractive route to complete battery replacement and/or decrease in the frequency of battery recharging cycles. Exploiting renewable energy resources in the device's environment, however, offers a power source limited by the device's physical survival rather than an adjunct energy store.

Recent motivation in environmental energy harvesting and energy scavenging has increased as low-power electronics, wireless standards, and miniaturization are increasingly prevalent in the form of sensor networks and mobile devices. Devices that experience a wide range of environmental conditions due to spatially and temporally diverse usage patterns require access to distributed energy sources and a relatively invariant power conversion efficiency dependence on energy intensity. Photovoltaic devices are one method to scavenge energy from local light sources, either in the outdoors from the sun or indoors from engineered light sources.

For portable electronics, the cost-per-area considerations are secondary, as most devices have small areas of exposed surface. To either power the devices in the steady state or contribute to a substantial extension of device lifetime, the photovoltaic devices generally are 1) used in high illumination conditions, 2) possess high power conversion efficiency, or 3) both. Additionally, true device portability is enhanced if the conversion efficiency is independent on illumination intensity and the direction of the light source(s). Existing photovoltaic devices can exhibit a strong dependence of conversion efficiency on local illumination conditions. These traits are undesirable for use in both outdoor conditions (ambient intensity 100 mW/cm²) and indoor lighting (ambient intensity 1-10 mW/cm²). In addition, photovoltaic devices made from crystalline semiconductors can exhibit a strong dependence of absorption efficiency on illumination direction. The substitution of photovoltaic devices with passive optical elements that redirect light, known as concentration, is a general method to increase the intensity of light incident on the device. Due to the logarithmic dependence of photovoltage with light intensity, optical concentration also typically results in higher power conversion efficiency. Accordingly, any one or more of the solar concentrators described herein may be electrically coupled to a photovoltaic cell and the overall assembly may be electrically coupled to the portable device to provide primary power, charging power or backup power to the portable device.

In certain embodiment, the solar concentrators described herein, when used in combination with a portable device, can provide significant advantageous characteristics including, but not limited to, (1) compatibility with both diffuse and direct illumination; the relative ratio of direct and diffuse light illumination is substantially higher for indoor versus outdoor environments; conventional photovoltaics are designed for maximal solar conversion efficiency and thus undergo significant performance degradation under purely diffuse lighting conditions; in these systems, the distribution of light absorption within the device thickness strongly affects electrical conversion efficiency (the spectral quantum efficiency varies with wavelength); in LSCs, the physical depth of the light absorption event does not affect light collection efficiency and thus can convert light with higher efficiency; (2) compatibility with diffuse light collection also allows simultaneous conversion of light absorbed over multiple collector faces; in a planar configuration, LSCs can concentrate light incident on both front and back sides of its large area faces; (3) increased optical intensity at the solar cells will increase electrical output compared to non-concentrated configurations; in addition, the lower ambient light intensity will not, when optically concentrated, overheat the solar cell, allowing passive thermal management to be employed; since each photon undergoes a bathochromic shift subsequent to absorption and preceding emission, extra energy is removed from the concentrated light that would otherwise contribute to heating potential conversion efficiency degradation; (4) for the portability of usage required of mobile electronics, it is desirable to achieve high conversion efficiencies when used under low lighting conditions (indoors), as a substantial fraction of use corresponds to these conditions. Incandescent bulbs are designed to match the spectral distribution of the sun; however, fluorescent bulbs are partly more efficient because they do not emit as much light in the infrared spectrum; as such, fluorescent indoor lighting contains a larger portion of its light spectrum within the visible band; low bandgap solar cells like silicon, cadmium telluride, and copper indium gallium selenide (1-1.4 eV) are ill-suited to extract high power from each photon since their bandgaps fall within the infrared—they are designed for sunlight. Solar cells with bandgaps in the visible frequencies enable higher electrical efficiencies as thermalization losses are reduced; put another way, the semiconductor bandgap(s) of single or multijunction solar cells that correspond to maximal power conversion efficiency for light incident from fluorescent bulbs are within the visible band instead of within the infrared band. LSCs can be designed to concentrate light at higher energies than that corresponding to the bandgap for optimal power conversion efficiency of outdoor light (about 1.1-1.3 V); as such, they can exhibit high conversion efficiencies when operating in indoor environments; (5) for devices where aesthetic appearance is important, the uniform (homogenous, or un-patterned) frontal appearance of LSCs possesses strong market advantages in segments where consumers value visual structure; in addition, the color of a LSC can be tailored at the time of manufacture, enabling visual customization, a substantial value in markets driven by aesthetic appearance, like personal entertainment, communication, and management devices.

Illustrative mobile devices that utilize batteries that can be either replaced, have their operational lifetime increased, or otherwise reduced in size, include but are not limited to: digital audio players (MP3, or “MPEG Layer-3”, or “Moving Picture Experts Group Layer 3” players), mobile phones (“cell phones” and portable phones), personal digital assistants (PDAs), portable computers (laptop computers), image sensors, cameras, mobile environmental sensors (for instance: audio, thermal, optical, vibrational, chemical, and weather monitoring) and other devices that commonly used batteries. For example, a solar concentrator may be placed on a surface of a vehicle, e.g., a car, recreational vehicle, golf cart, etc., to provide power to one or more battery storage devices used to provide starting, primary power or accessory power, e.g., power for operating air conditioning units, heating units, stoves, etc. in a recreational vehicle.

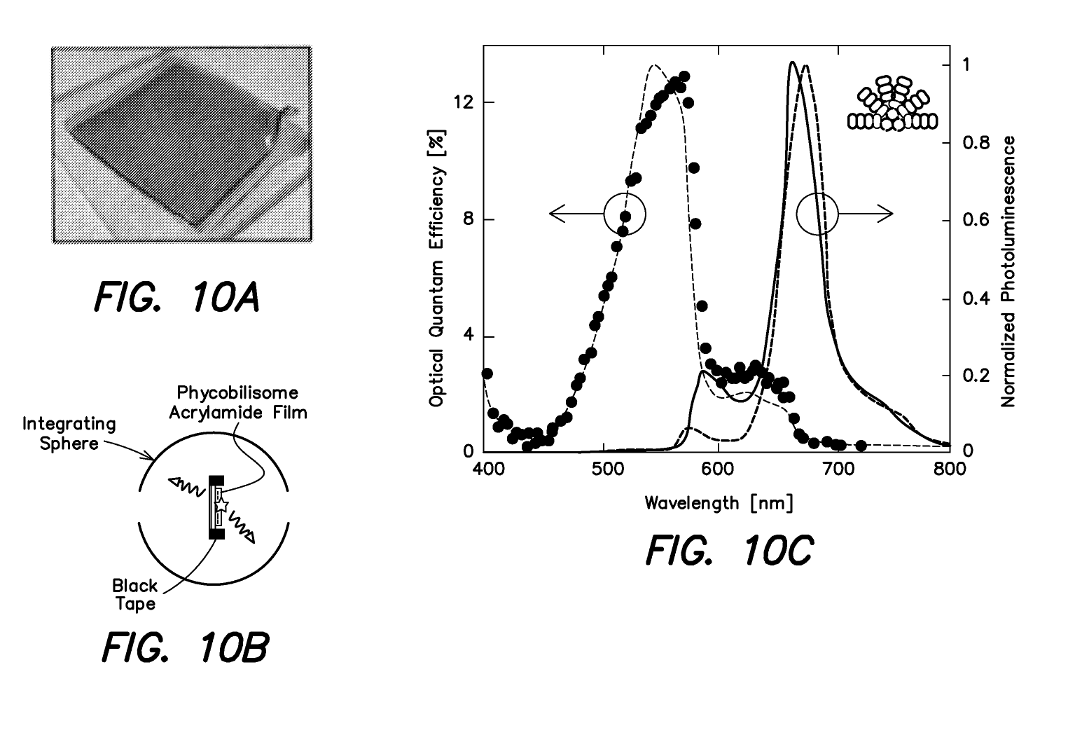

Two illustrative configurations of portable devices that are coupled to a solar concentrator are shown in FIGS. 9A and 9B. The dimensions in FIGS. 9A and 9B are arbitrary and no size or relative size should be implied or inferred. Referring to FIG. 9A, a portable device 910 is electrically coupled to a LSC/PV cell assembly 920 though interconnect 930. The LSC/PV cell assembly 920 is separate from the portable device 910, and current is supplied to the portable device 910 through the interconnect 920. The LSC of the LSC/PV assembly 920 may be any of those described herein, for example, those that include one or more of a chromophore assembly, an anti-Stokes material or both. Similarly, the PV cell of the LSC/PV cell assembly 920 may be any PV cell including the thin film PV cells described herein. In addition, the LSC/PV cell assembly may include more than one PV cell as described herein with respect to embodiments that include two or more PV cells, e.g., two or more PV cells having different efficiencies. Referring to FIG. 9B, an LSC/PV cell assembly 970 is shown as in the housing 960 of a portable device 950. The LSC/PV assembly 970 may be positioned along one or more surfaces that would receive incident light during operation or storage of the portable device. For example, the LSC/PV assembly 970 may be positioned on an upper surface of a mobile phone facing away from a user such that during use of the mobile phone, incident sunlight or ambient light may be captured by the LSC/PV cell assembly 970 to charge the mobile phone battery.

In embodiments where a LSC/PV cell assembly is used with a mobile device other suitable component, such as voltage converters, amplifiers, conditioners and the like may be used to provide a desired voltage output, waveform, intensity and the like. Such devices are conventionally known in the art and will be readily selected for use by the person of ordinary skill in the art, given the benefit of this disclosure.

In one embodiment, an LSC may be used for indoor light harvesting. For example, electronic shelf labels may include an LSC/PV cell assembly that can be electronically coupled to sensors, computers and the like. The electronic shelf label (ESL) may harvest light from indoor light sources, e.g., fluorescent bulbs, halogen bulbs, incandescent bulbs, light-emitting diodes, etc. used to provide ambient lighting in a room. The ESL may be electrically coupled to a device by placement on a shelf or by placement in the housing of the device. Irrespective of where the ESL is placed, the ESL desirably can receive incident light from the overhead light sources and convert that light to a current, which may be provided to the sensor, computer or other electronic device. In one embodiment, an LSC/PV assembly used in concert with a charge controller and energy storage device (i.e. battery or electronic capacitor) can be used to provide energy as the ESL requires.

The following examples serve to illustrate some of the novel features, aspect and examples of the technology disclosed herein and should not be construed as limiting the scope of the appended claims.

### Example 1

Phycobilisomes were used as a chromophore assembly to produce an LSC. To cast phycobilisomes in solid-state waveguides, they were incorporated within a matrix that mimics the native aqueous environment, while simultaneously providing a rigid substrate. Polyacrylamide hydrogels satisfy both requirements. See Kennan et al., Journal of Magnetic Resonance Series B 110, 267-277 (1996); Dickson, Science 274, 966-969 (1996); Franklin et al., Chemistry of Materials 14, 4487-4489 (2002). The matrix also possesses a high refractive index because the trapping efficiency for a waveguide with air cladding and a core refractive index of nₛ is given by ηₜᵣₐₚ=\sqrt{1−1/nₛ²}. For a glass (nₛ=1.5) waveguide with air cladding, ˜75% of the light is trapped. For a water-based waveguide (nₛ=1.33), the trapping efficiency is reduced to ηₜᵣₐₚ=66%.

To increase the refractive index and rigidity of the substrate, a polyacrylamide film having a lower water content than is normally used in polyacrylamide films for gel electrophoresis was used. To decrease stress in the film, an extra monomer with bulky groups, N-isopropyl acrylamide (NIPAM), was added to the acrylamide monomer to increase steric repulsion between chains. The ratio of the crosslinker (bis-acrylamide) was also decreased to yield a lower crosslinking density. Equal portions of a 40% (w/v) water based solution of 37.5:1 acrylamide/bisacrylamide solution (Sigma-Aldrich) and a 40% (w/v) solution of NIPAM (Sigma-Aldrich) in deoinized water was mixed thoroughly using a mini-vortexer (VWR). To this solution, a freshly prepared solution of ammonium persulfate (Sigma-Aldrich) was added up to a concentration of 1% (w/v) and vigorously mixed.

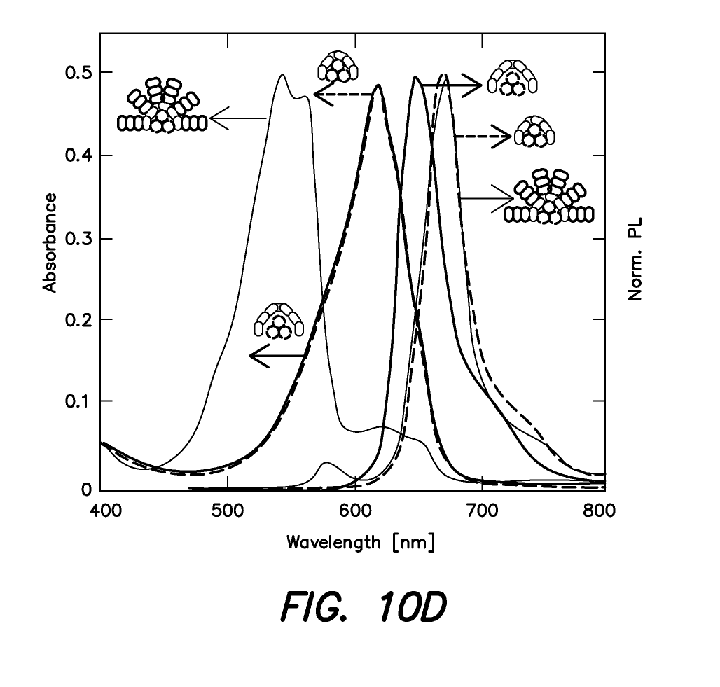

In a separate vial, dry phycobilisomes (Columbia Biosciences Corporation, 6440 Dobbin Road, Columbia Md. 21045) were rehydrated with 100 μL of 0.1M phosphate buffer, and to this solution a 1 mL solution of the monomeric acrylamide solution was added. To accelerate the polymerization 1.5 μL of TEMED (N,N′ tetramethylethylene diamine) (Sigma-Aldrich) was added. After gentle mixing, the resultant solution was allowed to polymerize at room temperature in a mini-hybridization chamber (Electron Microscopy Sciences). This resulted in smooth, flexible, optically clear films with a refractive index of nₛ=1.6, with square edges of length L=22 mm, a thickness of t=0.5 mm and a geometric gain (defined as the ratio of the facial area to the edge area) of G=L/4t=11 (see FIG. 10A). The geometric gain is a key LSC parameter. It measures the path length of photons within the waveguide, and it determines the maximum possible optical concentration in the LSC. Typically, re-absorption losses increase with G.

To enable characterization, the phycobilisome film was supported on a glass slide. The transmission of phycobilisome photoluminescence into the glass substrate was not observed, probably due to the presence of an air gap between the gel and the glass. The integrity of phycobilisomes in the films was examined by comparing the absorption and fluorescence spectra of phycobilisomes in films and in phosphate buffer, see FIG. 10C. Both the emission spectra in the phosphate buffer and in the acrylamide film show strong emission from APC and almost complete quenching of PE emission at λₘₐₓ=572 nm,⁴ suggesting the internal energy transfer path is largely preserved.

The optical quantum efficiency, η_{edge}, defined as the fraction of incident photons coupled to the edges of the solid-state films, was characterized within an integrating sphere; see FIG. 10B. Edge and facial LSC emission was discriminated by selectively blocking the edge emission with black tape and a black marker. The spectrally-resolved OQE was compared to the absorption of complexes in phosphate buffer in FIG. 10C. The OQE of the film as a function of excitation wavelength matched the absorption spectrum of phycobilisomes in their native environment, confirming that the optical properties of the phycobilisomes are well preserved in the solid state. The peak η_{edge}=12.5% compared to peak efficiencies exceeding η_{edge}=50% in organic solar concentrators that use thin film coatings of synthetic dyes.⁹ The lower performance of cast phycobilisome-based LSCs can be due to an absorption of only 70% of the incident light in the 0.5-mm-thick LSC, the observation of a relatively low photoluminescent efficiency for APC in the films (η_{PL}<50%) and significant facial emission (η_{face}=12%), probably due in part to scattering at the interface between the film and its glass substrate.

### Example 2

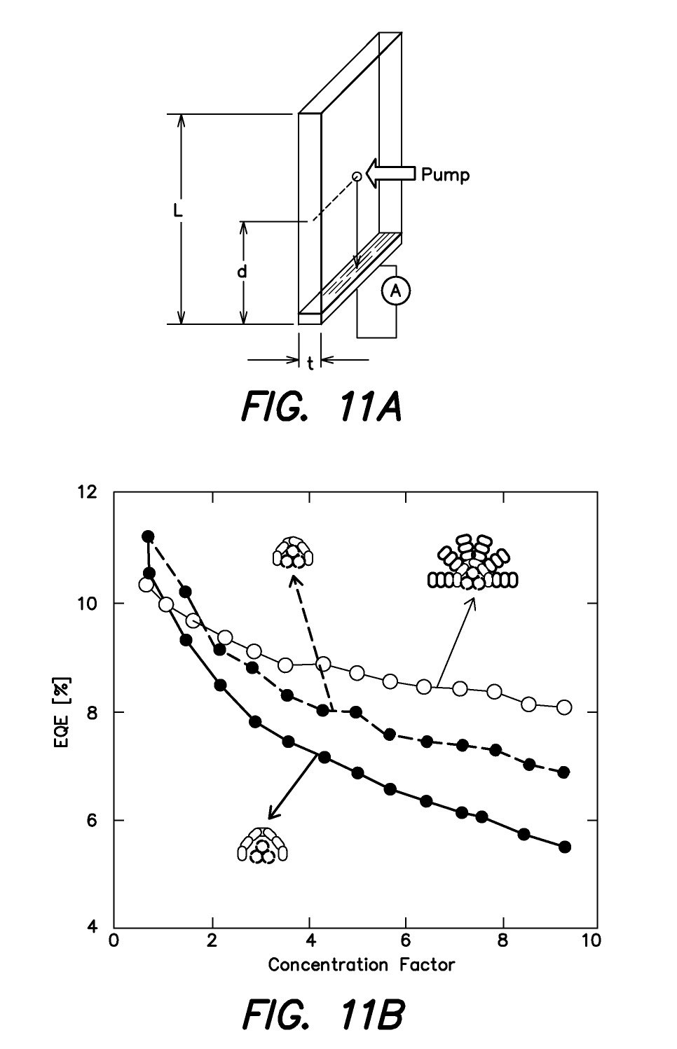

The effects of near field energy transfer on self absorption losses within the phycobilisome-based LSCs were examined. To eliminate any effects due to stress in the solid state films, these measurements were performed in aqueous LSCs shown schematically in FIG. 11A. 1-mm-thick sheets of glass (Erie Scientific, nₛ=1.5) were cut and glued together with epoxy (Epo-Tek 301, Epoxy Technology) to form an uncapped liquid-tight container with dimensions of 7.6 cm×7.6 cm×0.34 cm. A GaAs solar cell from Spectrolab with an external quantum efficiency (defined as electrons out per photon in) of ˜90% was cut into a 3.8 cm×0.34 cm strips. Two of these cells were connected in series, and attached to the bottom narrow face of the concentrator with index matching fluid (Norland Index Matching Liquid 150, refractive index 1.52, Norland Products Inc) and mechanical pressure. The two side narrow faces were blackened with an ink marker then covered with black plastic tape. The top narrow face was blackened by applying tape directly to the liquid interface. The tape was supported by the glass sheets that formed the other sides of the container. The blackening serves to prevent indirect luminescence from reaching the solar cell. The phycobilisome solution was diluted in a 0.75M phosphate buffer (pH 8.0) until the solution had an absorbance of 0.5 over a path length of 1 cm at the peak absorption wavelength.

The water-based LSCs employed three types of phycobilisomes, a fully coupled phycobilisome with three types of biliproteins (PE-PC-APC), a partially coupled complex with two types of biliproteins (PC-APC), and a fully decoupled complex with the same two types of biliproteins (PC-APC). The absorption and emission spectra of these phycobilisome complexes are shown in FIG. 10D. The fully coupled complexes possessed an abundance of PE, leading large Stokes shifts between the emission of APC at λ=680 nm and the peak absorption of PE at λ=545 nm. The partially coupled and fully decoupled complexes show smaller Stokes shifts. The absorbance of the partially coupled and fully decoupled PC-APC phycobilisome complexes peaks at a wavelength of λ=620 nm, where the PC protein has its peak absorption. The partially coupled PC-APC phycobilisomes show no evidence of PC fluorescence at λ=650 nm, suggesting full energy transfer to APC. For the decoupled complex, however, the observed emission was mostly due to decoupled PC chromophores that emit at λ=650 nm.

### Example 3

The external quantum efficiency (EQE) as a function of geometric gain G, for the liquid LSCs is shown in FIG. 11B. The EQE was measured at λ=620 nm for the partially coupled and fully decoupled complexes, and at λ=550 nm for the fully coupled complexes containing PE. Consistent with the absorption and emission data, the Förster-coupled complexes were observed to have the best performance at higher optical concentrations. To quantitatively compare the different complexes, we defined the self absorption loss as the decrease in EQE as a function of geometric gain relative to the EQE at G=1.4. A direct comparison was easiest between the fully coupled and partially decoupled complexes since they both emitted from APC. Over all measured geometric gains, the intact phycobilisome complexes exhibited a self absorption loss that was 48±5% lower than the partially decoupled phycobilisomes. The fully decoupled complexes had the highest self absorption losses of all due to the absence of energy transfer and the resulting emission by both PC and APC, resulting in a smaller Stokes shift. The unique self assembled nanostructure of phycobilisomes reduced re-absorption losses in LSCs by approximately 50%. Thus, phycobilisomes provided a structural model for synthetic LSC dyes and dye aggregates. In addition, phycobilisomes themselves can be stabilized in a solid-state LSC matrix with minimal loss of performance. Future phycobilisome-based devices may be significantly improved by coupling efficient synthetic dyes to APC. Additionally, the ratio of donor to acceptor pigments can be increased by selecting organisms with a better endogenous pigment ratio (either naturally occurring or through directed evolution). Finally, the protein environment of the terminal pigment can be molecular engineered to further red shift its absorption.

### Example 4

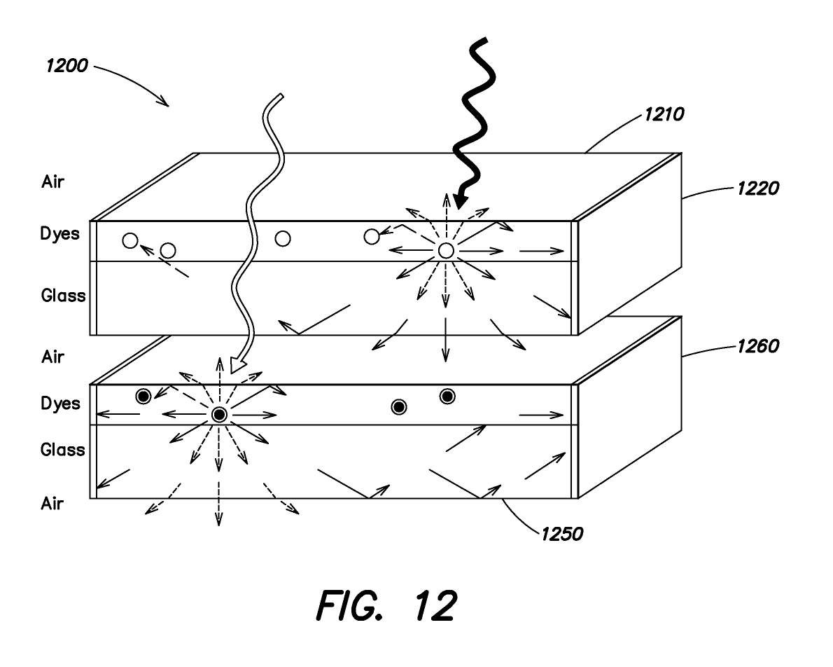

A tandem luminescent solar concentrator (LSC) may be produced stacking two or more waveguides onto each other or otherwise optically coupling two or more waveguides. Referring to FIG. 12, a tandem luminescent solar concentrator 1200 comprises a first waveguide 1210 disposed or stacked on a second waveguide 1250. The top waveguide 1210 may be configured to concentrate visible radiation on a solar cell 1220 coupled to the waveguide 1210. Solar cell 1220 may be, for example, a GalnP solar cell. The bottom waveguide 1250 may be configured to concentrate a different wavelength range of radiation on a solar cell 1260 coupled to the waveguide 1250. For example, the waveguide 1250 may include a chromophore that is configured to absorb radiation below 950 nm and provide such radiation to the solar cell 1260. The solar cell 1260 may be, for example, a silicon solar cell.

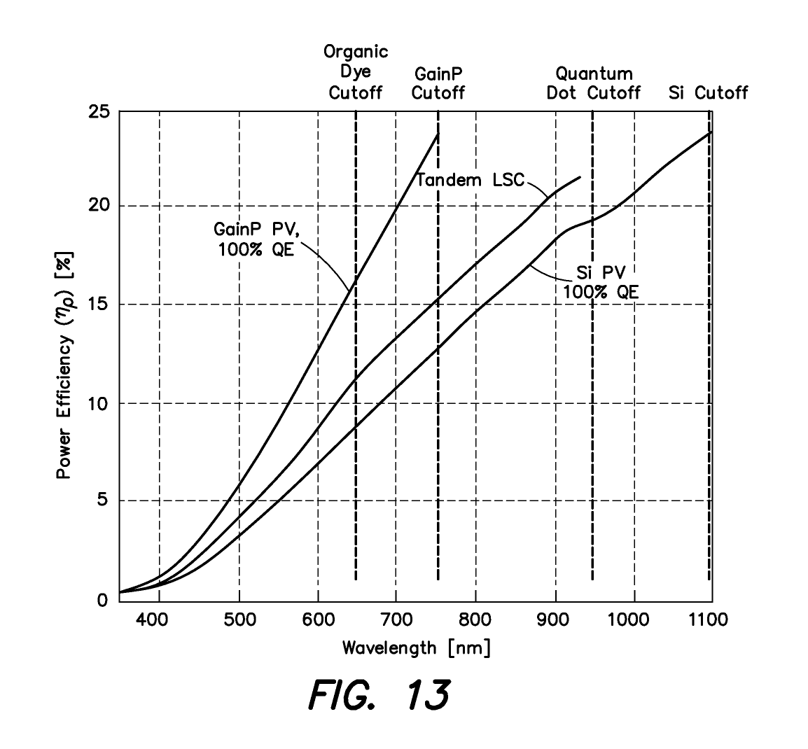

The projected performance of a tandem LSC is shown in FIG. 13. For a quantum efficiency of 70% in each waveguide, the total power efficiency of the combined waveguides is about 21%. The absorption cutoff for the top waveguide 1210 is taken to be 650 nm, and the absorption cutoff for the bottom waveguide 1250 is taken to be 950 nm. The model assumes a 100 nm shift between absorption and emission in the top waveguide 1210 and a 150 nm shift between absorption and emission in the bottom waveguide 1250 to lower self absorption. The model is based on the following description.

### Example 5

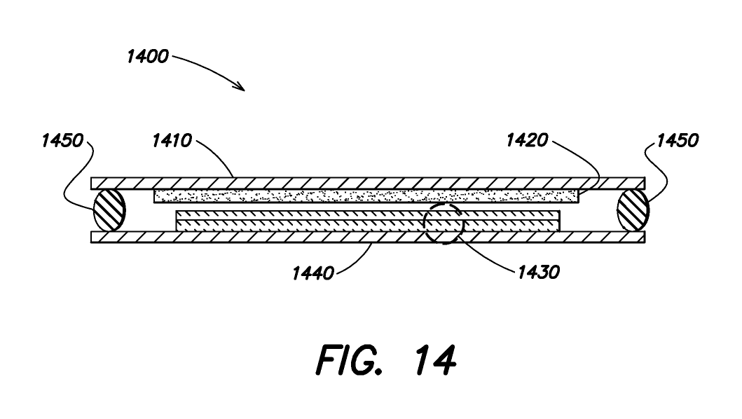

A key stability concern in LSCs is the emissive dye. This dye may be, for example a red or infrared emitter. Since work on LSCs was largely abandoned there has been significant investment in the research and development of organic light emitting devices (OLEDs). This work generated red OLEDs that now routinely exhibit half-lives exceeding 300,000 hours, or thirty years. Progress in OLED stability has been achieved through advances in dye molecule design and packaging. Both of these technologies are directly applicable to LSCs. An LSC may include one or more dessicants or getters to reduce the exposure of the dye to oxygen or other air sources, which may reduce the overall lifetime of the LSC. One example of this configuration is shown in FIG. 14. The LSC 1400 comprises a top plate 1410, a dessicant layer 1420, a dye 1430, a bottom plate 1440 and a sealant 1450 reducing or preventing ingress of oxygen into the body of the LSC 1400. The LSC 1400 may be coupled on one end to a PV cell (not shown). Illustrative dessicants include, but are not limited to, cellulose acetates, epoxies, phenoxies, siloxanes, methacrylates, sulfones, phthalates, amides, acrylates, methacrylates, cyclized polyisoprenes, polyvinyl cinnamates, epoxies, silicones, adhesives, and radiation-curable binders selected from the group consisting of radiation-curable photoresist compositions. The exact thickness of the dessicant layer may vary, and preferably the dessicant does not substantially interfere with absorption of radiation by the dye.

A table showing the stability of Universal Display Corporation's set of phosphorescent dye molecules is shown below.

| | η_{Q} | η_{PL}* | Lifetime to 50% |
|---|---|---|---|
| blue | 11% | 46% | 17,500 hrs @ 200 cd/m² |
| green | 19% | 71% | 250,000 hrs @ 1000 cd/m² |
| red | 20% | 80% | 330,000 hrs @ 1000 cd/m² |

### Example 6

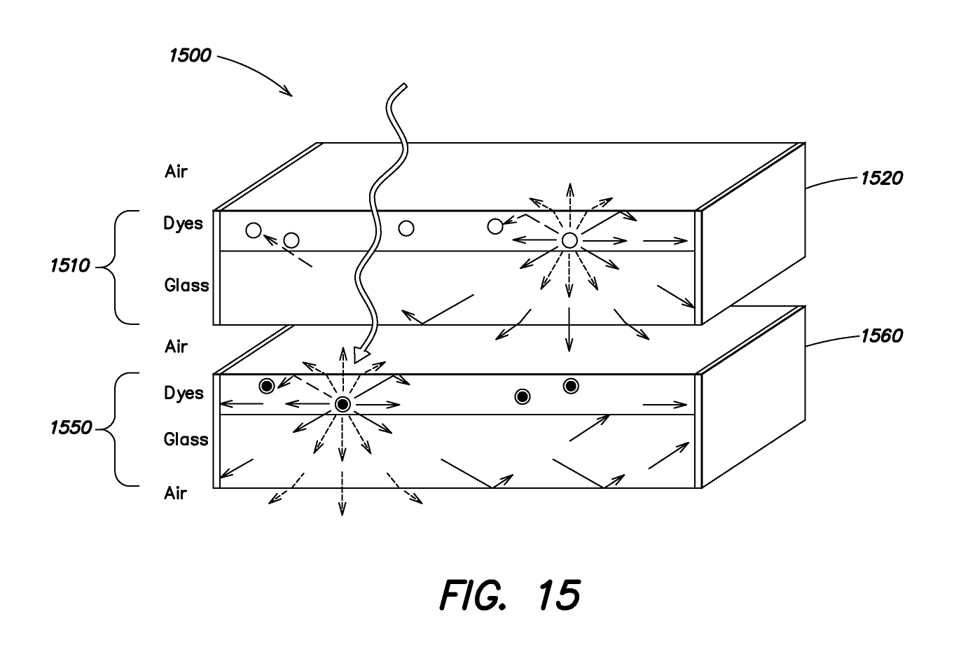

A tandem luminescent solar concentrator (LSC) may be produced stacking two waveguides onto each other. Referring to FIG. 15, a tandem luminescent solar concentrator 1500 comprises a first waveguide 1510 disposed or stacked on a second waveguide 1550. The top waveguide 1510 may be configured to concentrate visible radiation on a solar cell 1520 coupled to the waveguide 1510. Solar cell 1520 may be, for example, a GalnP solar cell. The bottom waveguide 1550 may be configured to concentrate a different wavelength range of radiation on a solar cell 1560 coupled to the waveguide 1550. In one embodiment, the solar cell 1560 may be a GaAs solar cell.

Top waveguide 1510 may be glass coated with an evaporated dye layer of composition tris-(8-hydroxyquinoline) aluminum (68.5%): rubrene (30%): 4-(dicyanomethylene)-2-t-butyl-6-(1,1,7,7-tetramethyljulolidyl-9-enyl)-4H-pyran (1.5%) (structures (III), (IV) and (V), respectively).

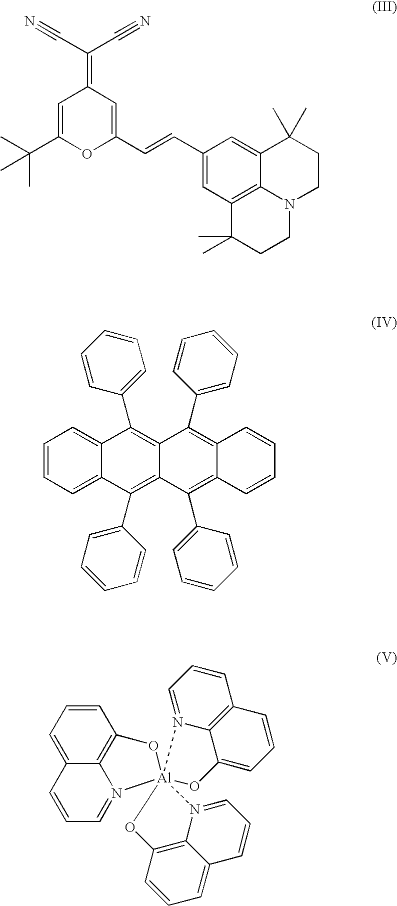

Bottom waveguide 1550 is glass coated with an evaporated dye layer of composition tris-(8-hydroxyquinoline) aluminum (94%): 4-(dicyanomethylene)-2-t-butyl-6-(1,1,7,7-tetramethyljulolidyl-9-enyl)-4H-pyran (1.5%) (2%): platinum tetraphenyltetrabenzoporphyrin(4%) (structures (V), (III) and (VI), respectively).

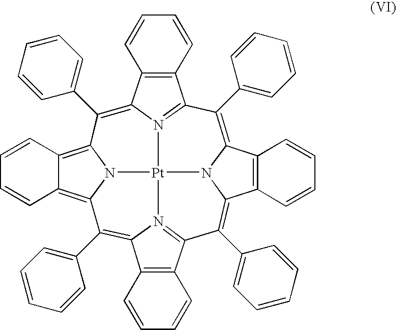

In addition, either one or both of the top or bottom layers may be coated with a chromophore assembly, an anti-Stokes material or both.

### Example 7

Experience with OLEDs has demonstrated that organic dyes can be stable for long periods if their package is extremely impermeable to oxygen and water. For example, the common OLED package shown in FIG. 12 employs glass and metal surfaces with an epoxy seal and a desiccant. In the LSC application, it is also desirable to protect both surfaces of the waveguide from scratches and defects that might promote scattering losses. Consequently, the LSC may be packaged in several ways to provide protection.

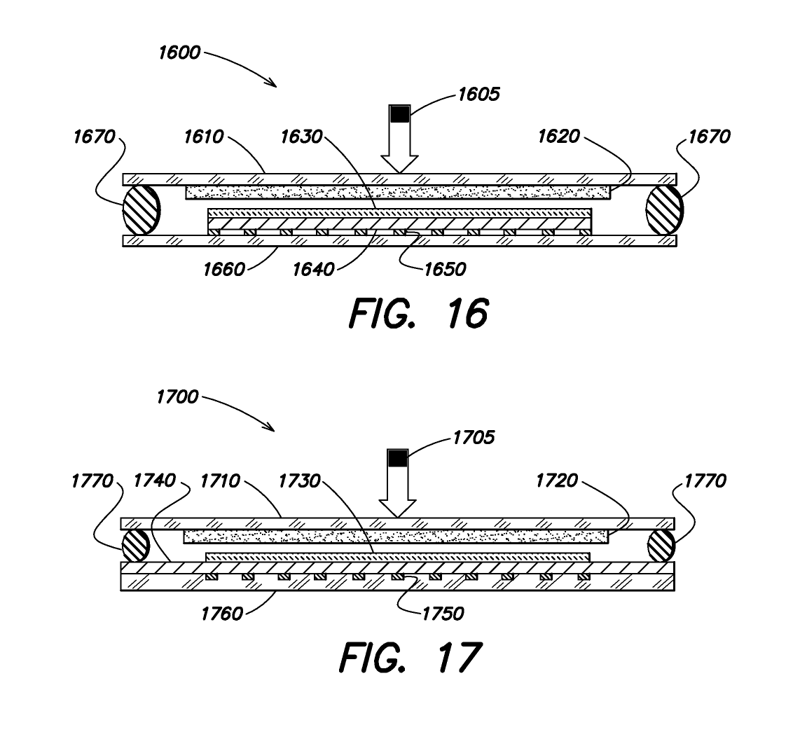

Referring to FIG. 16, a device 1600 comprises a top layer 1610, a dessicant layer 1620, at least one dye 1630 (which may be in a film and the dye be replaced with, or used in combination with, a chromophore assembly, an anti-Stokes material or both), a substrate 1640, a plurality of photovoltaic cells, such as photovoltaic cell 1650, a bottom layer 1660 and a spacer/sealant 1670. The device 1600 is configured to absorb incident radiation 1605. In some examples, the top layer 1610, the substrate 1640 and the bottom layer 1660 may each be, or may include, glass. In other examples, the bottom layer 1660 may be a reflective surface, e.g., a mirror, to enhance the absorption efficiency of the device 1600.

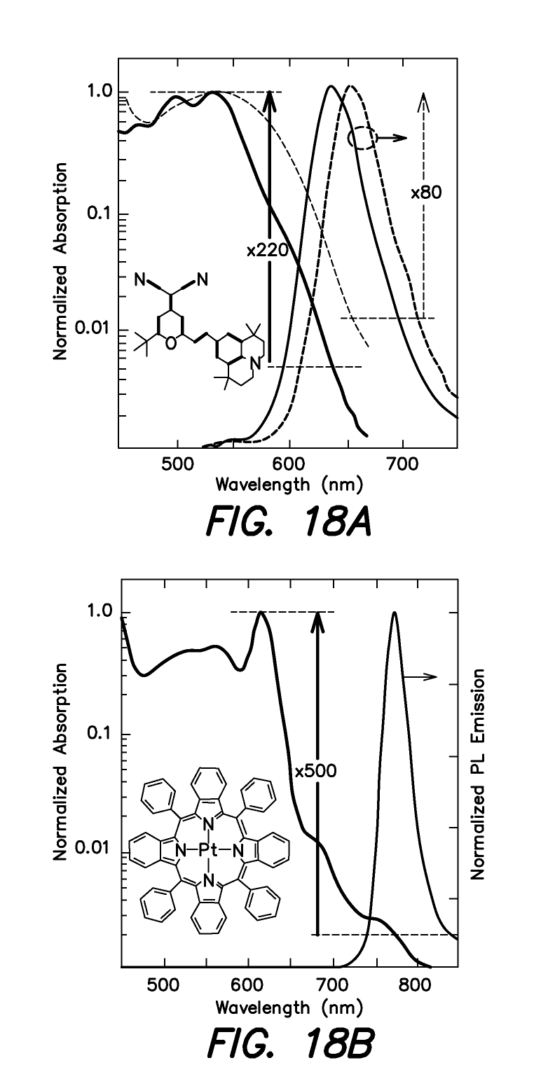

Referring to FIG. 17, a device 1700 comprises a top layer 1710, a dessicant layer 1720, at least one dye 1730 (which may be in a film and the dye be replaced with, or used in combination with, a chromophore assembly, an anti-Stokes material or both), a substrate 1740, a plurality of photovoltaic cells, such as photovoltaic cell 1750, a bottom layer 1760 and a spacer/sealant 1770. The device 1700 is configured to absorb incident radiation 1705. In some examples, the top layer 1710 and the substrate 1740 may each be, or may include, glass. In other examples, the bottom layer 1760 and/or the top layer 1710 may be replaced by a low refractive index polymer, and the glass substrate 1740 itself may be used to protect the dye 1730. This approach may reduce the overall weight of the device.

### Example 8

The self-absorption ratio, S, between the peak absorption of a given solar concentrator and its absorption at its emissive wavelength is a rough estimate of the maximum possible G. DCJTB belongs to the DCM class of laser dyes, characterized by large Stokes shifts and red emission with near unity quantum efficiency.

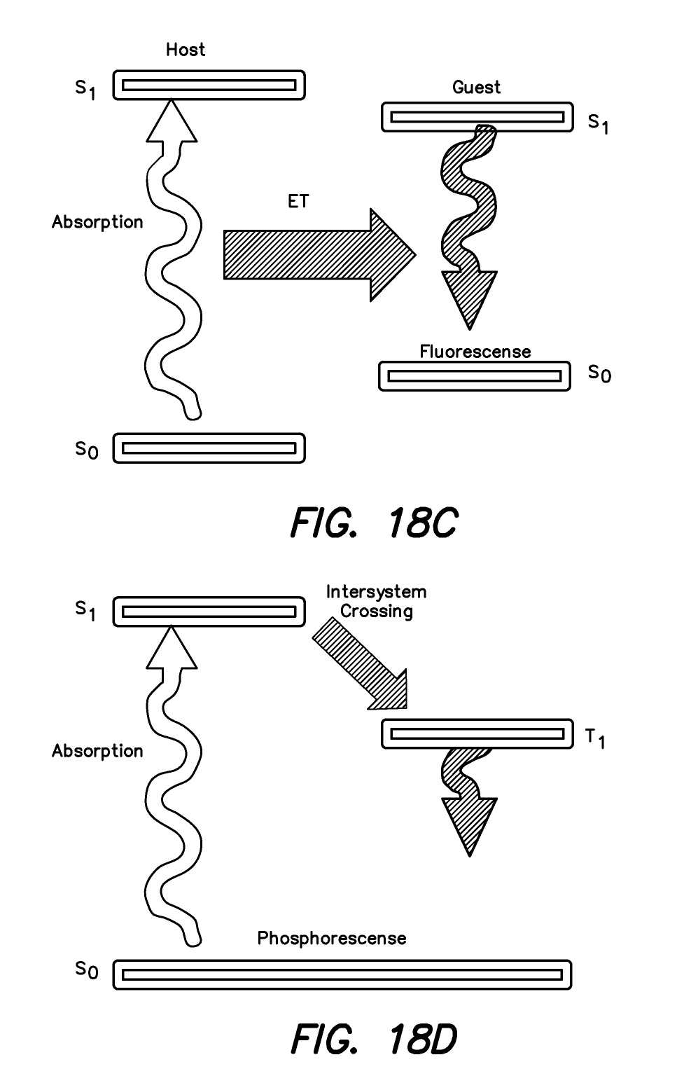

As shown in FIG. 18A, the self-absorption ratio for a DCJTB-based solar concentrator is approximately S=80. To control the concentration of DCJTB, it was co-deposited with the host material tris(8-hydroxyquinoline) aluminum (AlQ3), which is known to form stable amorphous films. The self-absorption ratio is enhanced when AlQ3 is used as the host, because both AlQ3 and DCJTB are polar molecules. The polar environment red-shifts the DCJTB photoluminescence (PL) via the solid state solvation effect, which is employed in OLEDs to adjust the emission color. Such polar environments may be used with a chromophore assembly or an anti-Stokes material, either by themselves or in combination with one or more other chromophores.

Förster energy transfer may be used to reduce the required concentration of the emissive dye. For example, in the rubrene-based solar concentrator of FIG. 18A, s rubrene:DCJTB ratio of 20:1 ratio can be used. Förster energy transfer from rubrene to DCJTB increases the self-absorption ratio of the rubrene-based OSC relative to the DCJTB-based OSC. Rubrene is non polar, however, and together with a slight reduction in the DCJTB concentration, this causes the DCJTB PL to shift approximately 20 nm back towards the blue. Similar ratios may be used where a chromophore assembly is used in combination with another chromophore, with the absorbing chromophore desirably being present in a larger amount. Similarly, where an anti-Stokes material is sued to absorb light and transfer energy to an emitting chromophore, the anti-Stokes material may be present in a larger amount as compared to the amount of emitting chromophore used.

Solar concentrators may also be produced using Pt(TPBP), which is phosphorescent in the infrared at wavelength of 770 nm with a PL efficiency of approximately 50%. It emits from a weakly-allowed triplet state relaxation. Compared to conventional fluorescent dyes, the emissive state of phosphorescent dyes is only weakly absorptive and typically exhibit large Stokes shifts. Indeed, the self-absorption ratio for the Pt(TPBP)-based OSC is approximately S=500; see FIG. 18B. The absorption of Pt(TPBP) is dominated by strong transitions from the Soret band at a wavelength of 430 nm and the Q band at a wavelength of 611 nm. To complete the absorption spectrum of Pt(TPBP)-based solar concentrators, DCJTB was added to fill in the Pt(TPBP) absorption spectrum and transfer energy to Pt(TPBP). Förster energy transfer and phosphorescence are illustrated schematically in FIGS. 18C and 18D, respectively.

The optical quantum efficiency (OQE), defined as the fraction of photons emitted from the edges of the OSC substrates, was determined within an integrating sphere. In an organic film refractive index of n=1.7 where all photons are re-emitted isotropically, approximately 80% of the photons are re-emitted into waveguide modes in the organic film or glass substrate. In the absence of self-absorption or scattering losses, these photons emerge from the edges of the solar concentrator and couple to the PV cell. The remaining photons are not subject to total internal reflection and are emitted into air through the top and bottom faces of the solar concentrator. Edge and facial emission may be distinguished by selectively blocking edge emission using black marker and tape.

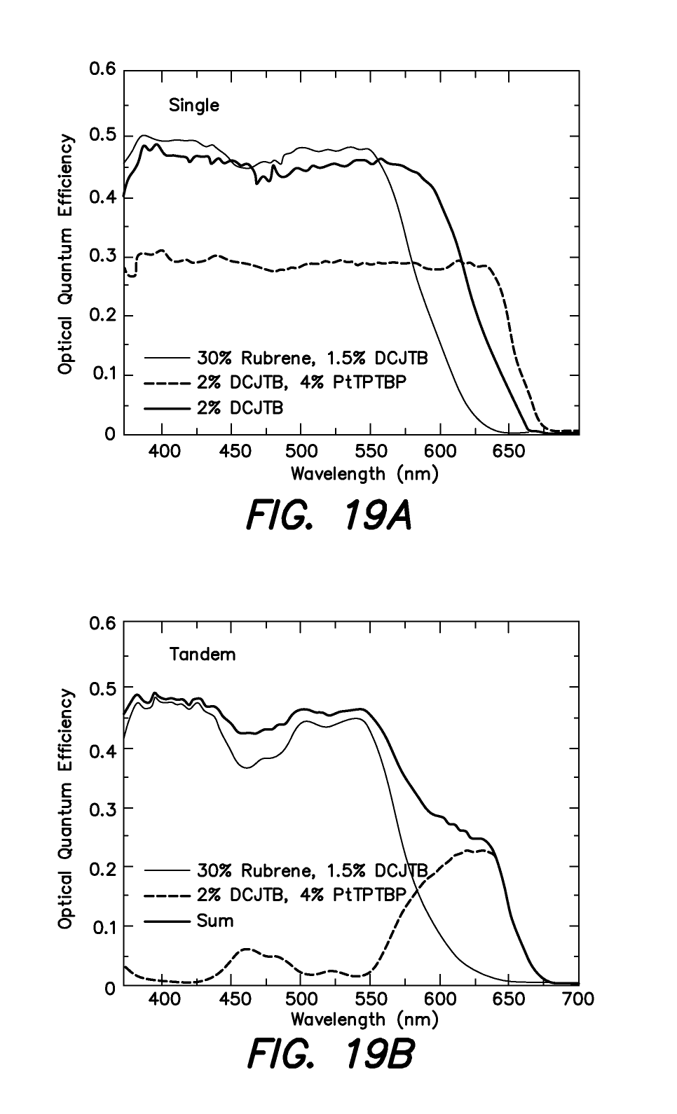

The OQEs of the single waveguide concentrators at low geometric concentration (G=3) are compared in FIG. 19A. A tandem waveguide solar concentrator was constructed using the rubrene-based solar concentrator on top to collect blue and green light and the Pt(TPBP)-based solar concentrator on the bottom to collect red light. Together, this tandem concentrator combines higher efficiency collection in the blue and green with lower efficiency performance further into the red; see FIG. 19B.

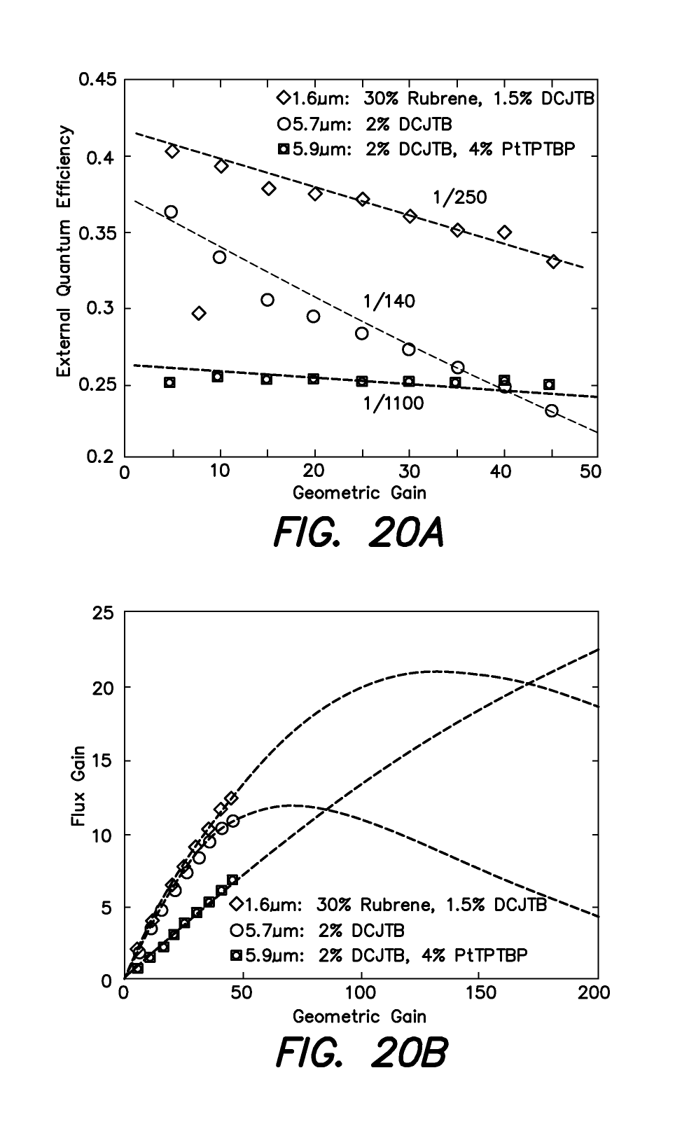

The external quantum efficiency (EQE) is the number of harvested electrons per incident photon and includes the coupling losses at the PV interface and the quantum efficiency of the PV. To obtain the EQE in the range G<50, the films were evaporated onto a 100 mm×100 mm×1 mm glass substrate with n=1.72. A 125 mm×8 mm strip of a Sunpower solar cell was attached to one entire edge of the substrate using EpoTek 301 epoxy. Note that the solar cell possesses an antireflection coating optimized for coupling from air. The remaining edges were blackened with marker to prevent reflections. The effect of increasing G is measured by sweeping a monochromatic excitation spot perpendicular to the attached solar cell and normalizing by solid angle. FIG. 20A shows the dependence of the EQE with G for each of the films, taken at the peak wavelength of the final absorbing dye (wavelength of 534 nm for DCJTB and wavelength of 620 nm for Pt(TPBP)). The DCJTB-based concentrator shows the strongest self-absorption. The self-absorption is lower in the rubrene-based concentrator, consistent with the spectroscopic data in FIG. 18A. Finally, the Pt(TPBP)-based concentrator shows no observable self-absorption loss for G<50. The data matches the theoretical performance assuming self-absorption ratios of S=140, S=250 and S=1100, for DCJTB, rubrene and Pt(TPBP)-based concentrators, respectively.

In FIG. 20B, the flux gain, F, for the three films coupled to bandgap-matched solar cells are compared utilizing the flux gain equation (flux=(geometric gain*efficiency of concentrator)/(efficiency of PV cell)). For G<50, all three films showed increasing flux gain with G. The power conversion efficiency was obtained from the optical quantum efficiency by integrating the product of the OQE, the AM1.5G spectrum and the external quantum efficiency of the solar cell as described, for example, in J. Palm et al., Solar Energy, 77 (2004) 757-765 and/or in S. H. Demtsu and J. R. Sites, “Quantification of losses in thin-film CdS/CdTe solar cells”, Thirty-first IEEE Photovoltaic Specialists Conference, 2005, pp. 347-350. Concentrators with emission from DCJTB may be paired with GalnP solar cells; those with emission from Pt(TPBP) may be paired with GaAs. The resulting power conversion efficiencies are listed in the table below.

| | Power Conversion | | |
|---|---|---|---|
| | efficiency at. G = 3, at | Flux gain | Projected |
| LSC | 50 | G = 50 | max. flux gain |
| DCJTB | 5.9%, 4.0% | 10 | 12 at G = 70 |
| rubrene | 5.5%, 4.7% | 12 | 21 at G = 130 |
| Pt(TPBP) | 4.1%, 4.1% | 6 | 32 at G = 500 |
| Tandem LSC | 6.8%, 6.1% | — | — |
| Tandem LSC-CdTe | 11.9%, 11.1% | 12 | 21 at G = 130 |
| PV | | | |
| Tandem LSC-CIGS | 14.5%, 13.8% | 12 | 21 at G = 130 |
| PV | | | |

The flux gains demonstrated above enable the use of high performance PV cells in low cost systems. A large flux gain may be most advantageous in >1 MW scale PV installations where the cost of the solar cells is paramount. In addition, the power conversion efficiency may be increased, for example, using a tandem LSC-thin film photovoltaic cell.

### Example 9

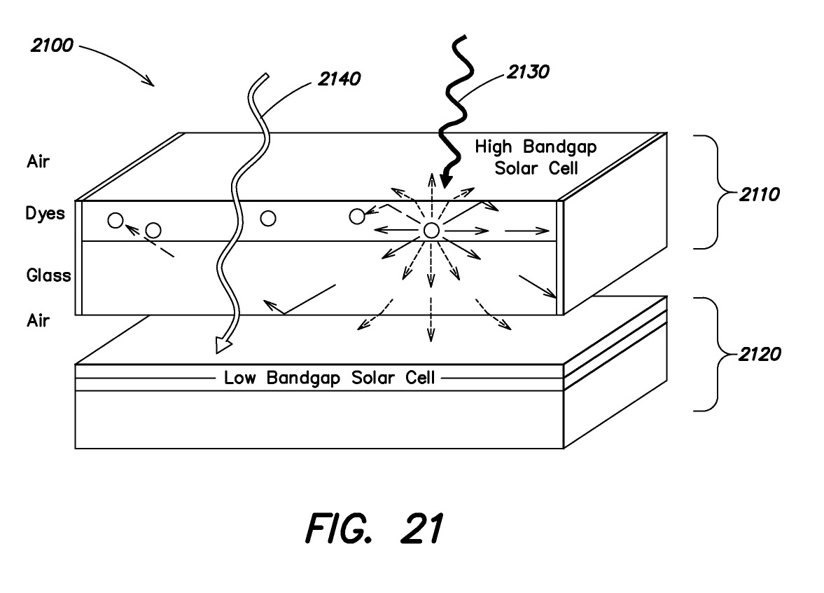

A solar concentrator may be coupled to a thin film photovoltaic cell as shown in FIG. 21. The device 2100 includes a solar concentrator 2110 coupled to a thin film PV cell 2120. Each of the devices 2110 and 2120 may be selected to absorb different wavelength ranges of light. For example, concentrator 2110 may be designed as a high bandgap solar cell such that certain light wavelengths 2130 are absorbed and other light wavelengths 2140 are transmitted through the device 2110 and absorbed by device 2120. The concentrator 2110 may include one or more of a chromophore assembly and an anti-Stokes material. The concentrator 2110 may also include one or more additional chromophores other than a chromophore assembly and/or an anti-Stokes material.

When introducing elements of the aspects, embodiments and examples disclosed herein, the articles “a,” “an,” “the” and “said” are intended to mean that there are one or more of the elements. The terms “comprising,” “including” and “having” are intended to be open-ended and mean that there may be additional elements other than the listed elements. It will be recognized by the person of ordinary skill in the art, given the benefit of this disclosure, that various components of the examples can be interchanged or substituted with various components in other examples.

Although certain aspects, examples and embodiments have been described above, it will be recognized by the person of ordinary skill in the art, given the benefit of this disclosure, that additions, substitutions, modifications, and alterations of the disclosed illustrative aspects, examples and embodiments are possible.

What is claimed is:

1. A solar concentrator comprising a substrate and chromophore assembly comprising a plurality of chromophores disposed on or in the substrate in a manner that at least one of the plurality of chromophores can receive at least some optical radiation, the chromophore assembly comprising an emitting chromophore effective to receive at least some energy by Förster energy transfer from the at least one chromophore of the chromophore assembly and emit at least some of the received energy at a wavelength that is red-shifted from the wavelength absorbed by the at least one of the plurality of chromophores in the chromophore assembly.

2. The solar concentrator of claim 1, in which the at least one chromophore that transfers energy to the emitting chromophore is part of the chromophore assembly.

3. The solar concentrator of claim 1, in which the at least one chromophore that transfers energy to the emitting chromophore is separate from the chromophore assembly.

4. The solar concentrator of claim 1, in which the chromophore assembly comprises a chromophore complex or a chromophore aggregate.

5. The solar concentrator of claim 1, in which the chromophore assembly is selected from the group consisting of a chlorin, a phycobilosome, a porphyrin, a cyanine dye and a perylene bisimide dye.

6. The solar concentrator of claim 1, further comprising a polar matrix in which the chromophore assembly is disposed.

7. The solar concentrator of claim 1, further comprising a first photovoltaic cell optically coupled to the solar concentrator.

8. The solar concentrator of claim 7, further comprising a second photovoltaic cell optically coupled to the solar concentrator; wherein the efficiency of the first and second photovoltaic cells is different.

9. A solar concentrator comprising:
a substrate; and
at least two chromophores disposed on or in the substrate in a manner that at least one of the chromophores can receive at least some optical radiation, in which one of the at least two chromophores comprise an anti-Stokes material and the other of the at least two chromophores is effective to receive energy from the anti-Stokes material by Förster energy transfer and emit at least some of the transferred energy at a wavelength that is blue-shifted from the wavelength absorbed by the anti-Stokes material.

10. The solar concentrator of claim 9, in which the anti-Stokes material is selected from the group consisting of lanthanide complexes, thulium doped silicate glasses, europium complexes, terbium complexes, samarium complexes, dysprosium complexes, inorganic rare earth ions, inorganic rare earth crystals, bulk phosphor material, europium-activated yttriumoxysulphide, rare earth oxide nanocrystals, fluorides containing europium, chlorides containing europium, lanthanide phosphors, inorganic crystal lattice with trivalent rare earth dopants, yttriumoxysulphide activated with erbium and ytterbium, upconverting phosphor nanopowders, anti-Stokes phosphors FCD-546-1, FCD-546-2, FCD-546-3, FCD-660-2, FCD-660-3 and FCD-660-4, anti-Stokes phosphor LPG-IR-3, and laser detection anti-Stokes” phosphors PTIR545/UF, PTIR550/F and PTIR660/F.

11. The solar concentrator of claim 10, in which the chromophore that receives energy from the anti-Stokes material is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines, oxazine, Exciton LDS series dyes, Nile Blue, Nile Red, DODCI, Epolight 5548, BASF Lumogen dyes including 083, 170, 240, 285, 305, 570, 650, 765, 788, 850, oligorylenes, dyes including DTTC1, Steryl 6, Steryl 7, prradines, indocyanine green, styryls, dioxazines, naphthalimides, thiazines, stilbenes, IR132, IR144, IR140, Dayglo Sky Blue (D-286) and Columbia Blue (D-298).

12. The solar concentrator of claim 10, further comprising a first photovoltaic cell optically coupled to the solar concentrator.

13. The solar concentrator of claim 12, further comprising a second photovoltaic cell optically coupled to the solar concentrator, wherein the efficiency of the first and second photovoltaic cells is different.

14. A solar concentrator comprising:
a substrate; and
at least two chromophores disposed on or in the substrate in a manner that at least one of the chromophores can receive at least some optical radiation, in which one of the at least two chromophores comprises an exciton fission material and the other of the at least two chromophores is effective to receive energy from the exciton fission material by Förster energy transfer and emit at least some of the transferred energy at a wavelength that is red-shifted from the wavelength absorbed by the exciton fission material.

15. The solar concentrator of claim 14, in which the exciton fission material is selected from the group consisting of the polyacenes, tetracene, pentacene, rubrene, rare earth phosphors, ytterbium, neodymium, rare earth organo-metallic complexes, and quantum dots.

16. The solar concentrator of claim 14, further comprising a first photovoltaic cell optically coupled to the solar concentrator.

17. The solar concentrator of claim 16, further comprising a second photovoltaic cell optically coupled to the solar concentrator; wherein the efficiency of the first and second photovoltaic cells is different.

18. A solar concentrator comprising:
a substrate; and
at least two chromophores disposed on or in the substrate in a manner that at least one of the chromophores can receive at least some optical radiation, in which one of the at least two chromophores comprises an exciton fission material and the other of the at least two chromophores is effective to receive energy from the exciton fission material by radiative energy transfer and emit at least some of the transferred energy at a wavelength that is red-shifted from the wavelength absorbed by the exciton fission material.

19. The solar concentrator of claim 18, in which the exciton fission material is selected from the group consisting of the polyacenes, tetracene, pentacene, rubrene, rare earth phosphors, ytterbium, neodymium, rare earth organo-metallic complexes, and quantum dots.

20. The solar concentrator of claim 18, further comprising a first photovoltaic cell optically coupled to the solar concentrator.

21. The solar concentrator of claim 20, further comprising a second photovoltaic cell optically coupled to the solar concentrator; wherein the efficiency of the first and second photovoltaic cells is different.
